(19) United States
(12) Patent Application Publication
(10) Pub. No.: US 2025/0329657 A1
(43) Pub. Date: Oct. 23, 2025

(54) SEMICONDUCTOR PACKAGE

(71) Applicant: LG INNOTEK CO., LTD., Seoul (KR)

(72) Inventor: Won Suk JUNG, Seoul (KR)

(73) Assignee: LG INNOTEK CO., LTD., Seoul (KR)

(21) Appl. No.: 18/867,361

(22) PCT Filed: May 23, 2023
(86) PCT No.: PCT/KR2023/007024

§ 371 Date: Nov. 19, 2024

(30) Foreign Application Priority Data
May 23, 2022 (KR) 10-2022-0062619

(51) Int. Cl. H01L 23/538; H01L 23/00; H01L 25/04

(52) U.S. Cl. CPC H01L 23/5383; H01L 23/562; H01L 25/043

(57) ABSTRACT

A semiconductor package according to an embodiment includes circuit board; and a connection member embedded in the circuit board, wherein the circuit board includes a first insulating layer not having a reinforcing member, the connection member is embedded in the first insulating layer of the circuit board, and the connection member includes a second insulating layer including an organic material.

### TECHNICAL FIELD

An embodiment relates to a semiconductor package.

### BACKGROUND ART

Higher performance of electric/electronic products is progressing, and accordingly, technologies for attaching a larger number of packages to a substrate of a limited size are being proposed and researched. However, a general package is based on mounting one semiconductor device, and thus, there is a limit to obtaining desired performance.

A general semiconductor package has a form in which a processor package in which a processor chip is disposed and a memory package in which a memory chip is attached are connected as one. A semiconductor package is provided a processor chip and a memory chip as one integrated package, and thus has advantages of reducing a mounting region of the chip and enabling high-speed signals through a short path.

The semiconductor package as described above has the advantages, it is widely applied to mobile devices and the like.

On the other hand, a size of a package has recently increased due to high specification of an electronic device such as a mobile device and adoption of HBM (High Bandwidth Memory), and accordingly, a semiconductor package including an interposer is mainly used. In this case, the interposer is provided with a silicon substrate.

However, when an interposer such as a silicon substrate is applied, there are problems in that a cost for manufacturing the interposer is high and formation of a Through Silicon Via (TSV) is complicated.

In addition, a semiconductor package including a silicon-based interconnect bridge is conventionally provided. When a silicon-based interconnect bridge is applied, there is a reliability issue due to a mismatch in coefficient of thermal expansion (CTE) between a silicon material of the bridge and an organic material of the substrate, and there is a problem of deterioration of power integrity characteristics.

### DISCLOSURE

### Technical Problem

The embodiment provides a semiconductor package having a novel structure.

In addition, the embodiment provides a semiconductor package in which a plurality of processor chips can be mounted side-by-side.

In addition, the embodiment provides a semiconductor package in which a plurality of processor chips and a memory chip can be mounted side-by-side.

In addition, the embodiment provides a semiconductor package including a processor chip and a passive device embedded in a circuit board.

Technical problems to be solved by the proposed embodiments are not limited to the above-mentioned technical problems, and other technical problems not mentioned can be clearly understood by those skilled in the art to which the embodiments proposed from the following descriptions belong.

### Technical Solution

A semiconductor package according to an embodiment comprises a circuit board; and a connection member embedded in the circuit board, wherein the circuit board includes a first insulating layer not having a reinforcing member, the connection member is embedded in the first insulating layer of the circuit board, and the connection member includes a second insulating layer including an organic material.

In addition, the first insulating layer includes a first layer, a second layer disposed on the first layer and having a cavity; and a third layer disposed on the second layer and filling the cavity, and the connection member is disposed in the cavity.

In addition, the second insulating layer of the connection member includes a polyimide.

In addition, the circuit board further includes a third insulating layer disposed under the first insulating layer, and the third insulating layer includes an insulating material different from the first insulating layer.

In addition, the third insulating layer includes a reinforcing member.

In addition, the circuit board further includes a fourth insulating layer disposed under the third insulating layer, and the fourth insulating layer includes a same insulating material as the first insulating layer.

In addition, the third insulating layer has a through hole, and a semiconductor device is disposed in the through hole.

In addition, the first insulating layer is disposed to fill the through hole and cover the semiconductor device.

In addition, the through hole includes a plurality of holes provided in the third insulating layer and spaced apart from each other in the horizontal direction, and the semiconductor device is respectively disposed within the plurality of through holes.

In addition, the plurality of through holes do not overlap with the connection member in a vertical direction.

A circuit board according to an embodiment comprises a first substrate; and a second substrate of a bridge substrate embedded in the first substrate, wherein the first substrate comprises a first insulating layer; a first circuit layer disposed on the first insulating layer; and a first via penetrating the first insulating layer; wherein the first insulating layer of the first substrate comprises a first layer; a second layer disposed on the first layer and including a first cavity in which the second substrate is disposed; and a third layer disposed on the second layer and embedding the second substrate, wherein the first to third layers of the insulating layer of the first substrate do not include glass fiber, and the second substrate includes an insulating layer including an organic material.

In addition, the first to third layers of the first insulating layer of the first substrate include an ABF (Aginomoto Build-up Film).

In addition, the insulating layer of the second substrate includes polyimide.

In addition, the first substrate further includes a second insulating layer of the first substrate disposed under the first layer of the first insulating layer of the first substrate, and the second insulating layer of the first substrate includes glass fiber.

In addition, the first substrate further includes a third insulating layer of the first substrate disposed under the second insulating layer of the first substrate, and the third insulating layer of the first substrate includes a same insulating material as the first insulating layer of the first substrate.

In addition, the first via of the first substrate includes a first-first via penetrating the first layer of the first insulating layer; a first-second via penetrating the second layer of the first insulating layer; and a first-third via penetrating the third layer of the first insulating layer, and the first circuit layer of the first substrate includes a first-first circuit layer disposed on the first layer of the first insulating layer; a first-second circuit layer disposed on the second layer of the first insulating layer; and a first-third via circuit layer disposed on the third layer of the first insulating layer.

In addition, the semiconductor package further comprises a first device disposed in a second cavity penetrating the second insulating layer of the first substrate, and the second cavity and the first device are covered with the first layer of the first insulating layer of the first substrate.

In addition, the first-first via of the first substrate includes a first sub-via that does not overlap with the first device in a thickness direction and does not directly contact a terminal of the first device; and a second sub-via that is spaced from the first sub-via in a horizontal direction, overlaps with the first device in the thickness direction, and is directly connected to the terminal of the first device; and at least one of a thickness and a width of the first sub-via is different from at least one of a thickness and a width of the second sub-via.

In addition, the semiconductor package further comprises a second device disposed in a third cavity penetrating the second insulating layer of the first substrate, wherein the third cavity and the second device are covered with the first layer of the first insulating layer of the first substrate, and the second cavity and the third cavity are spaced apart within the second insulating layer of the first substrate in a horizontal direction, and the first cavity does not overlap with the second cavity and the third cavity in the thickness direction.

In addition, the first-third via of the first substrate includes a first sub-via overlapping the second substrate in the thickness direction and directly connected to a pad layer of the second substrate; and a second sub-via of the first-third via spaced apart from the first sub-via of the first-third via in a horizontal direction and not directly connected to the pad layer of the second substrate, and at least one of a thickness and width of the first sub-via of the first-third via is different from at least one of a thickness and width of the second sub-via of the first-third via.

In addition, the first-first circuit layer of the first substrate includes a pad part overlapping the first cavity in the thickness direction and having an upper surface exposed through the first cavity, and the second substrate is attached to the pad part by an adhesive layer disposed on the pad part.

In addition, the second substrate includes a first circuit layer of the second substrate disposed on an upper surface of the insulating layer of the second substrate, a second circuit layer of the second substrate disposed on a lower surface of the insulating layer of the second substrate, and a via of the second substrate penetrating the insulating layer of the second substrate, wherein a slope of a side surface of the via of the second substrate is different from a slope of a side surface of the first-first via of the first substrate.

In addition, the first circuit layer of the second substrate includes a first metal layer including at least one of nickel and chromium; and a second metal layer disposed on the first metal layer and including copper.

In addition, the slope of the side surface of the via of the second substrate is closer to a right angle than a slope of the side surface of the first-first via of the first substrate.

In addition, the second substrate includes a first protective layer disposed on the insulating layer of the second substrate and including an opening overlapping the first circuit layer of the second substrate in a thickness direction.

In addition, the second substrate further includes a second protective layer disposed under the insulating layer of the second substrate and entirely covering a lower surface of the second circuit layer of the second substrate, and the adhesive layer is disposed on a lower surface of the second protective layer of the second substrate.

In addition, the second substrate includes a pad layer directly connected to the first-third via of the first substrate, and a position of an upper surface of the pad layer of the second substrate is different from a position of an upper surface of the first-second circuit layer of the first substrate.

In addition, a thickness of each of the first to third layers of the first insulating layer of the first substrate has a first difference from a thickness of the second insulating layer of the first substrate, and a height of an upper surface of the pad layer of the second substrate and a height of an upper surface of the first-second circuit layer of the first substrate has a second difference, and the second difference is smaller than the first difference.

### Advantageous Effects

The circuit board of the embodiment includes a first insulating layer and a second insulating layer. The second insulating layer may include a prepreg. Accordingly, the embodiment can maintain a rigidity of the circuit board to improve bending characteristics, thereby improving the product reliability. In addition, the first insulating layer includes ABF. Accordingly, the embodiment can reduce a size of a circuit layer and a via disposed on the first insulating layer. Specifically, the embodiment can form a circuit layer and a via of a fine pattern connected to a first processor chip and the second processor chip on the first insulating layer.

In addition, the first insulating layer includes a plurality of layers. In addition, a circuit layer and a via are disposed on each of the plurality of layers of the first insulating layer. At this time, the embodiment allows the circuit layer and via formed on the first insulating layer to gradually increase toward the second insulating layer. Accordingly, the embodiment can minimize signal transmission loss between the circuit layer and the via disposed on the first insulating layer and the circuit layer and the via disposed on the second insulating layer. Accordingly, the embodiment can improve communication characteristics of the circuit board.

In addition, the circuit board of the embodiment includes a bridge substrate embedded in the first insulating layer. The bridge substrate can be disposed in a first cavity formed in a second layer of the first insulating layer and covered with a third layer of the first insulating layer. In addition, the embodiment allows a pad layer included in the bridge substrate and the via penetrating the first insulating layer to be directly connected. Accordingly, the embodiment can minimize a signal transmission distance and further minimize the signal transmission loss.

In addition, the insulating layer of the bridge substrate of the embodiment has a CTE similar to that of the first insulating layer. Furthermore, an insulating layer of the bridge substrate of the embodiment has flexible characteristics. Specifically, the insulating layer of the bridge substrate can include polyimide (PI), which is an organic material. Accordingly, the embodiment can reduce a product unit cost compared to a bridge substrate including conventional silicon.

In addition, the bridge substrate of the embodiment includes a pad layer. The pad layer is directly connected to the first via disposed in the first insulating layer. At this time, an alignment state between the pad layer of the bridge substrate and the first via greatly affects the product reliability of the circuit board and the semiconductor package. At this time, in the embodiment, transparent polyimide is applied as the insulating layer of the bridge substrate. Accordingly, the embodiment can improve the alignment between the pad layer of the bridge substrate and the first via disposed on the first insulating layer. Accordingly, the embodiment can improve the overall product reliability.

In addition, the embodiment can stably protect the bridge substrate from stress generated during thermal deformation of the circuit board.

That is, in a conventional technology, the insulating layer of the bridge substrate includes silicon. Accordingly, the conventional bridge substrate has rigid characteristics due to the silicon. Accordingly, the stress generated when the circuit board was thermally deformed was directly transmitted to the bridge substrate. Accordingly, the conventional bridge substrate had reliability problems such as cracks.

In contrast, the insulating layer of the bridge substrate of the embodiment includes polyimide. Accordingly, a flow of the bridge substrate together with the first insulating layer can be achieved when the circuit board is thermally deformed. Accordingly, the embodiment can improve the physical reliability and electrical reliability of the bridge substrate.

Furthermore, the embodiment can easily control a thickness of the bridge substrate. For example, in a conventional case including silicon, a process of polishing a silicon substrate must be performed in order to control a thickness of the bridge substrate, and therefore, it was difficult to control the thickness of the bridge substrate to a desired thickness due to the difficulty of the process characteristics.

In contrast, the embodiment can easily control the entire thickness of the bridge substrate, and accordingly, the thickness of the bridge substrate can be easily controlled in accordance with a depth of a cavity formed in the first insulating layer. Accordingly, the embodiment can minimize a thickness difference between a first sub-via in direct contact with the bridge substrate and sub-vias excluding the first sub-via. Accordingly, the embodiment can improve the overall physical reliability and electrical reliability of the circuit board.

### DESCRIPTION OF DRAWINGS

FIG. 1 is a cross-sectional view showing a semiconductor package according to a comparative example.

FIG. 2 is a cross-sectional view showing a circuit board according to an embodiment.

FIG. 3 is an enlarged cross-sectional view of a portion of a first insulating layer of FIG. 2.

FIG. 4 is a cross-sectional view showing a bridge substrate according to a first embodiment.

FIG. 5 is a cross-sectional view showing a bridge substrate according to a second embodiment.

FIG. 6 is a view showing a bridge substrate according to a third embodiment.

FIG. 7 is a cross-sectional view showing a layer structure of a redistribution layer according to a first embodiment.

FIG. 8 is a view showing a layer structure of a redistribution layer according to the second embodiment.

FIG. 9 is a cross-sectional view explaining a step between a first-second circuit layer and a pad layer of a bridge substrate according to a first embodiment.

FIG. 10 is a view explaining a step between a first-second circuit layer and a pad layer of a bridge substrate according to a second embodiment.

FIGS. 11 to 25 are views explaining the circuit board of FIG. 2 in order of processes.

FIG. 26 is a view showing a semiconductor package according to a first embodiment.

FIG. 27 is a view showing a semiconductor package according to a second embodiment.

### BEST MODE

Hereinafter, embodiments of the present disclosure will be described in detail with reference to the accompanying drawings.

However, the spirit and scope of the present disclosure is not limited to a part of the embodiments described, and can be implemented in various other forms, and within the spirit and scope of the present disclosure, one or more of the elements of the embodiments can be selectively combined and redisposed.

In addition, unless expressly otherwise defined and described, the terms used in the embodiments of the present disclosure (including technical and scientific terms) can be construed the same meaning as commonly understood by one of ordinary skill in the art to which the present disclosure belongs, and the terms such as those defined in commonly used dictionaries can be interpreted as having a meaning that is consistent with their meaning in the context of the relevant art. In addition, the terms used in the embodiments of the present disclosure are for describing the embodiments and are not intended to limit the present disclosure.

In this specification, the singular forms can also include the plural forms unless specifically stated in the phrase, and can include at least one of all combinations that can be combined in A, B, and C when described in “at least one (or more) of A (and), B, and C”. Further, in describing the elements of the embodiments of the present disclosure, the terms such as first, second, A, B, (a), and (b) can be used.

These terms are only used to distinguish the elements from other elements, and the terms are not limited to the essence, order, or order of the elements. In addition, when an element is described as being “connected”, “coupled”, or “contacted” to another element, it can include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” can include not only when two elements are directly connected to each other, but also when one or more other elements are formed or disposed between two elements. Further, when expressed as “on (over)” or “under (below)”, it can include not only the upper direction but also the lower direction based on one element.

### Comparative Example

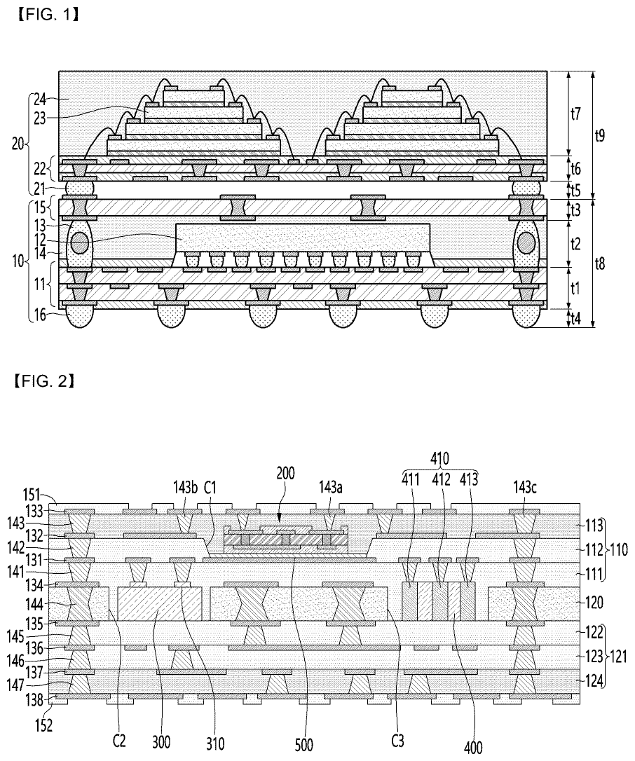

FIG. 1 is a cross-sectional view showing a semiconductor package according to a comparative example.

Referring to FIG. 1, in a comparative example, at least two packages are required to transmit signals to a main board of an electronic device.

The semiconductor package included in the electronic device in the comparative example can be a combination of at least two or more packages.

The semiconductor package according to the comparative example includes a first package 10 and a second package 20.

The first package 10 is a processor package on which a processor chip 12 is mounted. And, the second package 20 is a memory package in which a memory chip 23 is mounted.

The first package 10 includes a first substrate 11 on which the processor chip 12 is mounted. The first substrate 11 has a multi-layer structure and includes one side on which the processor chip 12 is disposed and the other side on which a first adhesive ball 16 is disposed. The first package 10 has a fan-out structure and is attached to the main board (not shown) of the electronic device using the first adhesive ball 16 disposed on the other side.

The processor chip 12 is mounted on the first substrate 11. The processor chip 12 is an integrated processor chip that integrates various functions. Accordingly, a size of the processor chip 12 increases in proportion to the number of functions it provides. The first substrate 11 allows the processor chip 12 to be mounted and has a function of connecting the processor chip 12 and the main mode of the electronic device.

Meanwhile, the first package 10 of the comparative example further includes a second substrate 15. The second substrate 15 is an interposer that interconnects the first package 10 and the second package 20.

That is, the semiconductor package in the comparative example essentially includes an interposer such as the second substrate 15. In addition, the semiconductor package in the comparative example has a problem in that an overall volume increases in proportion to a thickness of the interposer. Accordingly, a thickness of the electronic device in the semiconductor package of the comparative example increases, and there is a limit to slimming.

In addition, the semiconductor package in the comparative example has a problem in that a length of the signal transmission line increases as the first package 10 and the second package 20 are interconnected using the second substrate 15. That is, in the semiconductor package in the comparative example, in order to transmit the signals of the processor chip 12 and the signals of the memory chip 23, they must pass through at least the second substrate 15, and accordingly, the signal transmission distance between the processor chip 12 and the memory chip 23 increases corresponding to the length of the signal transmission line of the second substrate 15. Accordingly, in the comparative example, there is a problem that high-speed communication between the processor chip 12 and the memory chip 23 is difficult due to the second substrate 15. Furthermore, the comparative example has a structure vulnerable to noise as the signal transmission distance by the second substrate 15 increases, and thus communication performance decreases.

Meanwhile, the first package 10 of the comparative example includes a second adhesive ball 13 disposed on the first substrate 11, and a first molding layer 14 that molds the second adhesive ball 13 and the processor chip 12. At this time, the first molding layer 14 protects the processor chip 12 and the second adhesive ball 13. Accordingly, a thickness of the first molding layer 14 is determined by a height of the processor chip 12 and the second adhesive ball 13. However, the comparative example further includes the second substrate 15 disposed over the first molding layer 14, and accordingly, the thickness of the first molding layer 14 increases because the influence of the second substrate 15 must also be considered.

In addition, the second package 20 of the comparative example includes a third substrate 22, a memory chip 23 disposed on the third substrate 22, and a second molding layer 24.

As described above, in the comparative example, at least three substrates are required to electrically connect the processor chip 12 and the memory chip 23 to each other. In addition, in the comparative example, a process for bonding at least three substrates to each other is required, and accordingly, there is a problem of decreased yield due to an increase in the number and complexity of manufacturing processes. Specifically, the comparative example requires at least three substrates due to the difficulty of a process of mounting different chips on one substrate.

In addition, in the comparative example, at least two adhesive balls are required to bond at least three substrates to each other.

That is, the comparison example includes a second adhesive ball 13 for connecting the first substrate 11 and the second substrate 15, and a third adhesive ball 21 for connecting the second substrate 15 and the third substrate 22. Accordingly, the semiconductor package according to the comparative example requires at least two adhesive balls to bond a plurality of substrates to each other, and has a problem in that the reliability of the semiconductor package can be deteriorated due to poor connection of the adhesive balls. In addition, it has a structure in which two or more adhesive balls are disposed in the thickness direction, and there is a problem that the thickness of the semiconductor package, and further the thickness of the electronic device increase by the thickness of the adhesive balls.

Specifically, the first substrate 11 has a first thickness t1 of 120 μm to 150 μm. A second thickness t2 including the first molding layer 14, the processor chip 12, and the second adhesive ball 13 is 145 μm to 160 μm. In addition, a third thickness t3 of the second substrate 15 is 90 μm to 110 μm. In addition, a fourth thickness t4 of the first adhesive ball 16 is 130 μm to 150 μm.

Accordingly, a total thickness t8 of the first package 10 including the first to fourth thicknesses t1, t2, t3, and t4 is 480 μm to 550 μm.

In addition, a fifth thickness t5 of the third adhesive ball 21 is 145 μm to 180 μm. In addition, a sixth thickness t6 of the third substrate 22 is 90 μm to 110 μm. In addition, a seventh thickness t7 including the memory chip 23 and the second molding layer 24 is 370 μm to 400 μm. Accordingly, a total thickness 19 of the second package 20 including the fifth to seventh thicknesses t5, t6, and t7 is 610 μm to 700 μm. Accordingly, a total thickness of the semiconductor package in the comparative example is 1100 μm or more.

Meanwhile, due to the recent slimming of electronic devices, the thickness of the semiconductor package is required to be 1100um or less. In addition, recently, a type of electronic device is mainly foldable products, and the foldable product has a characteristic that the restrictions in the length direction are small, but the restrictions in the thickness direction are great. However, since the semiconductor package of the comparative example has a structure in which a plurality of substrates are bonded to each other through a plurality of adhesive balls in the thickness direction, there is a problem in that it does not satisfy the specifications required by electronic devices.

In addition, as the performance of electrical/electronic products has recently improved, technologies for attaching a larger number of packages to a limited-sized substrate are being researched, and thus, there is a demand for finer circuit patterns. However, in a case of the semiconductor package of the comparative example, there is a limit to miniaturization of the circuit pattern. The circuit pattern included in the semiconductor package of the comparative example has a line width of at least 10 μm and a spacing of at least 10 μm. In addition, as the number of functions processed in an application processor (AP) has recently increased, it has become difficult to implement them on a single chip. However, in the case of the circuit pattern provided in the comparative example, it is difficult to mount two application processors (APs) performing different functions on the one first substrate 11.

The embodiment is intended to solve the problems of the comparative example, and provides a circuit board with a novel structure on which a plurality of application processor chips can be mounted on one board and a semiconductor package including the same.

Furthermore, the embodiment is intended to solve the problems of the comparative example, and provides a circuit board with a novel structure capable of mounting an application processor chip and a memory chip side by side, and a semiconductor package including the same.

### Electronic Device

Before describing an embodiment, an electronic device to which a semiconductor package of the embodiment is applied will be briefly described. An electronic device includes a main board (not shown). The main board can be physically and/or electrically connected to various components. For example, the main board can be connected to the semiconductor package of the embodiment. Various semiconductor devices can be mounted on the semiconductor package. Broadly, the various semiconductor devices mounted on the semiconductor package can include a memory chip such as a volatile memory (e.g., DRAM), a non-volatile memory (e.g., ROM), and a flash memory, an application processor chip such as a central processor (e.g., CPU), a graphics processor (e.g., GPU), a digital signal processor, a cryptographic processor, a microprocessor, and a microcontroller, and a logic chip such as an analog-to-digital converter and an application-specific IC (ASIC).

In addition, the embodiment provides a semiconductor package that can mount at least two different types of chips on one substrate while reducing the thickness of the semiconductor package connected to the main board of the electronic device.

In this case, the electronic device can include a smart phone, a personal digital assistant, a digital video camera, a digital still camera, a network system, a computer, a monitor, a tablet, a laptop, a netbook, a television, a video game, a smart watch, an automotive, and the like. However, the embodiment is not limited thereto, and can be any other electronic device that processes data in addition to these.

### Embodiment

Hereinafter, a circuit board and a semiconductor package including the circuit board according to an embodiment will be specifically described.

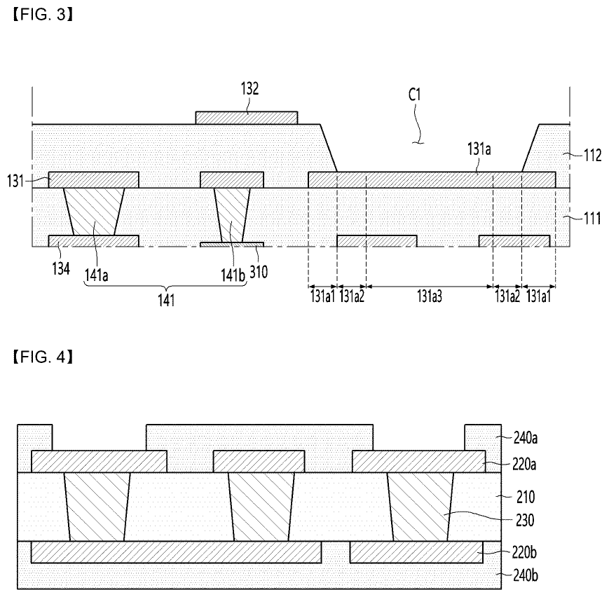

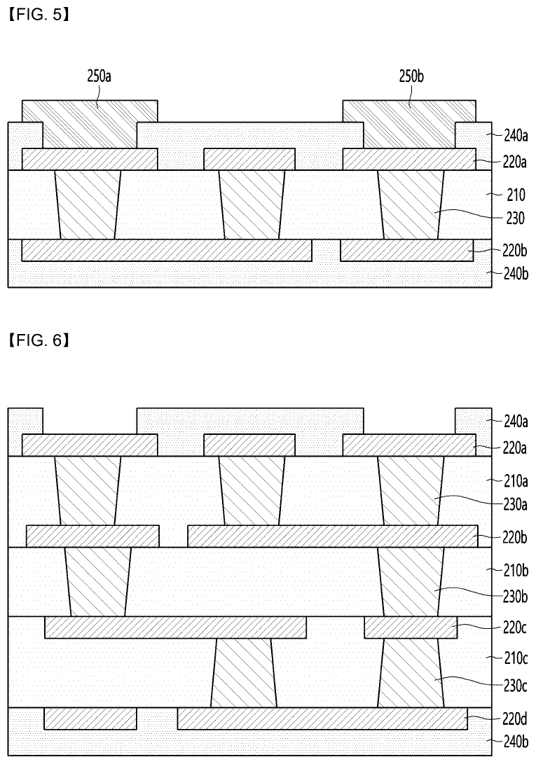

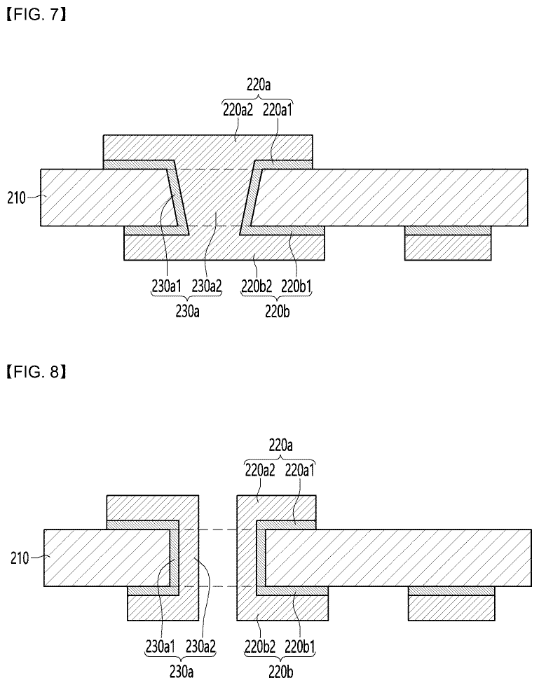

FIG. 2 is a cross-sectional view showing a circuit board according to an embodiment, FIG. 3 is an enlarged cross-sectional view of a portion of a first insulating layer of FIG. 2, FIG. 4 is a cross-sectional view showing a bridge substrate according to a first embodiment, FIG. 5 is a cross-sectional view showing a bridge substrate according to a second embodiment, FIG. 6 is a view showing a bridge substrate according to a third embodiment, FIG. 7 is a cross-sectional view showing a layer structure of a redistribution layer according to a first embodiment, and FIG. 8 is a view showing a layer structure of a redistribution layer according to the second embodiment.

Hereinafter, a circuit board according to an embodiment will be described with reference to FIGS. 2 to 8.

Referring to FIGS. 2 to 8, the circuit board of the embodiment can be configured to mount at least two different chips.

For example, the circuit board of the embodiment can include a plurality of chip mounting regions in which at least two processor chips can be mounted.

For example, the circuit board of the embodiment can include a plurality of chip mounting regions in which one processor chip and one memory chip can be mounted.

For example, the circuit board of the embodiment can include a plurality of chip mounting regions in which at least one processor chip and at least one memory chip can be mounted.

A configuration of the circuit board of the embodiment excluding a bridge substrate 200 can be referred to as a ‘first substrate’, and the bridge substrate 200 can be referred to as a ‘second substrate’. Preferably, the bridge substrate 200 can be referred to as a connection member connecting a plurality of semiconductor devices, and other components except for the bridge substrate can be referred to as a circuit board embedding the connection member.

In addition, the circuit board includes devices 300 and 400 embedded in the substrate together with the bridge substrate 200. The devices 300 and 400 can be embedded in the circuit board in multiple numbers. For example, the devices 300 and 400 can be embedded in multiple numbers while being horizontally spaced apart from each other in the circuit board.

Meanwhile, in the circuit board of the embodiment, a first insulating layer 110, a second insulating layer 120, a third insulating layer 121 can each be referred to as a substrate insulating layer. Furthermore, first to third circuit layers disposed on the first insulating layer 110, the second insulating layer 120, and the third insulating layer 121 can be referred to as a substrate circuit layer. In addition, first to third vias disposed in the first insulating layer 110, the second insulating layer 120, and the third insulating layer 121 may be referred to as a substrate via. In addition, a first protective layer 151 disposed on the first insulating layer 110 may be referred to as a first substrate protective layer. In addition, a second protective layer 152 disposed under the third insulating layer 121 may be referred to as a second substrate protective layer.

Meanwhile, the bridge substrate also includes an insulating layer, a circuit layer, a via, and a protective layer. Accordingly, in order to distinguish each component of the circuit board and the bridge board, an insulating layer included in the bridge substrate may be referred to as a bridge insulating layer. In addition, a circuit layer included in the bridge substrate may be referred to as a bridge circuit layer. In addition, a via included in the bridge substrate may be referred to as a bridge via. In addition, a protective layer included in the bridge substrate may be referred to as a bridge protective layer.

The circuit board may include a plurality of insulating layers.

For example, the circuit board may include a first insulating layer 110, a second insulating layer 120, and a third insulating layer 121.

The first insulating layer 110 may refer to an insulating layer region in which a processor chip is mounted among a plurality of insulating layers. In addition, the first insulating layer 110 may refer to an insulating layer region in which a bridge substrate 200 is disposed. That is, the first insulating layer 110 may refer to an insulating layer in which a bridge substrate 200 connecting between the plurality of processor chips is embedded while providing a mounting region in which a plurality of processor chips are mounted. The first insulating layer 110 may be formed of a plurality of layers. For example, the first insulating layer 110 may be formed of first to third layers 111, 112, and 113 from a lower side. However, the embodiment is not limited thereto, and the first insulating layer 110 may have a layer structure of two or less layers, or may have a layer structure of four or more layers.

The second insulating layer 120 may be disposed on one surface of the first insulating layer 110. The second insulating layer 120 may be disposed on a lower surface of the first insulating layer 110. The second insulating layer 120 may include an insulating material different from that of the first insulating layer 110. The second insulating layer 120 may include an insulating material having higher rigidity than the first insulating layer 110. The second insulating layer 120 may refer to an insulating layer region in which the devices 300 and 400 are embedded among the plurality of insulating layers.

The third insulating layer 121 may be disposed under the second insulating layer 120. The third insulating layer 121 may have a symmetrical structure with respect to the first insulating layer 110 with respect to the second insulating layer 120. The third insulating layer 121 may mean an insulating layer region among a plurality of insulating layers that is connected to a main board. For example, the third insulating layer 121 may mean an insulating layer region among a plurality of insulating layers that is connected to an electronic device. A number of layers of the third insulating layer 121 may be same as a number of layers of the first insulating layer 110. Accordingly, the third insulating layer 121 may include the first layer to the third layer 122, 123, and 124. However, the embodiment is not limited thereto. For example, the third insulating layer 121 may have a greater number of layers than the first insulating layer 110, or may have a smaller number of layers than the first insulating layer 110.

The first insulating layer 110 may include a first insulating material. In addition, the second insulating layer 120 may include a second insulating material different from the first insulating material. The third insulating layer 121 may include a first insulating material similar to the insulating material of the first insulating layer 110.

The second insulating layer 120 may be a core layer. Accordingly, the circuit board of the embodiment may be a core substrate including a core layer. However, the embodiment is not limited thereto. For example, the second insulating layer 120 may mean an insulating layer disposed at an inner layer among a plurality of insulating layers, not a core layer. Accordingly, the circuit board of the embodiment may be a coreless substrate.

The second insulating layer 120 may include a prepreg. The second insulating layer 120 may be a prepreg in which glass fibers are impregnated into a resin. The second insulating layer 120 may include a resin and glass fibers disposed in the resin. The glass fibers may also be called a reinforcing member. In addition, the reinforcing member can be distinguished from a composition such as filler. The resin may be an epoxy resin, but is not limited thereto. Hereinafter, the second insulating layer 120 is described as being a core layer.

The second insulating layer 120 may be a CCL (Clad copper laminate) including prepreg (PPG), or may include materials such as silicon, sapphire, glass, and ceramic. However, the second insulating layer 120 of the embodiment may include glass or sapphire, which are transparent materials. Accordingly, a modulus rigidity of the second insulating layer 120 may improve overall warpage characteristics of the circuit board. In addition, the circuit board of the embodiment includes a plurality of insulating layers. In addition, sizes of the circuit layers or vias disposed in the plurality of insulating layers may be different from each other. For example, at least one circuit layer or via may have a size for being connected to a bridge substrate 200 or a processor chip. In addition, at least one other circuit layer or via may have a size for connecting to the devices 300 and 400. In addition, at least another circuit layer or via may have a size for connecting to a main board. Accordingly, the embodiment requires electrical connection reliability between each circuit layer or via. Here, the electrical connection reliability may include alignment between vias disposed in each layer.

At this time, the second insulating layer 120 of the embodiment is formed of a transparent material such as sapphire or glass. Accordingly, the embodiment is advantageous in adjusting upper and lower alignment due to the transparent characteristic of the second insulating layer 120, and thus can improve the processability and product quality. For example, the embodiment can increase the positional accuracy when forming a via in the second insulating layer 120, can increase the alignment characteristic in an exposure and development process, and can easily check whether the circuit layers disposed on a surface are defective.

The second insulating layer 120 may include a plurality of cavities. For example, the second insulating layer 120 may include a second cavity C2 and a third cavity C3. The second cavity C2 and the third cavity C3 may penetrate the second insulating layer 120. The second cavity C2 and the third cavity C3 may be spaced apart in a horizontal direction (for example, in a length direction or a width direction) within the second insulating layer 120. The second cavity C2 and the third cavity C3 may provide a space in which the devices 300 and 400 are disposed.

For example, the second cavity C2 may provide a space in which a first device 300 is disposed. In addition, the third cavity C3 may provide a space in which a second device 400 is disposed. A width of the second cavity C2 may be larger than a width of the first device 300. Accordingly, at least a portion of the second cavity C2 may be filled with the first insulating layer 110. For example, the second cavity C2 may include a first region in which the first device 300 is disposed, and a second region other than the first region filled with the first insulating layer 110.

In addition, a width of the third cavity C3 may be larger than a width of the second device 400. Accordingly, at least a portion of the third cavity C3 may be filled with the first insulating layer 110. For example, the third cavity C3 may include a third region in which the second device 400 is disposed, and a fourth region other than the third region filled with the first insulating layer 110.

The second cavity C2 and the third cavity C3 may not overlap a first cavity C1 in a vertical direction (or thickness direction). The first cavity C1 is formed in the first insulating layer 110 and provides a space in which a bridge substrate 200 is disposed.

The embodiment can improve overall warpage characteristics of the circuit board by preventing the first cavity C1, the second cavity C2, and the third cavity C3 from overlapping in the vertical direction. Furthermore, the embodiment can minimize signal interference between the bridge substrate 200 disposed in the first cavity C1 and the devices 300 and 400 disposed in the second cavity C2 and the third cavity C3. Accordingly, the embodiment can improve signal characteristics of the circuit board. That is, the embodiment can improve the electrical reliability and physical reliability of the circuit board through an arrangement structure of the cavities as described above.

The first insulating layer 110 is disposed on the second insulating layer 120. The first insulating layer 110 can be composed of multiple layers.

The first insulating layer 110 may include a first layer 111, a second layer 112, and a third layer 113. For example, the first insulating layer 110 may have a three-layer structure. However, the embodiment is not limited thereto. The first layer 111, the second layer 112, and the third layer 113 of the first insulating layer 110 may include an insulating material different from that of the second insulating layer 120. For example, the first insulating layer 110 may not include glass fiber. As an example, the first insulating layer 110 may include a photocurable resin or a photosensitive resin. For example, the first insulating layer 110 may include ABF (Aginomoto Build-up Film). However, the embodiment is not limited thereto. For example, the first insulating layer 110 may include a PID (Photo Imageable Dielectric).

The first insulating layer 110 may include a first cavity C1.

The first layer 111 of the first insulating layer 110 refers to a layer adjacent to the second insulating layer 120 and in which the first cavity C1 is not formed. In addition, the second layer 112 of the first insulating layer 110 refers to a layer in which the first cavity C1 is formed. In addition, the third layer 113 of the first insulating layer 110 refers to a layer that is disposed on the second layer 112 and fills the first cavity C1.

In addition, the first insulating layer 110 may have four or more layers. When the first insulating layer 110 has four or more layers, the first layer 111 may have more layers than the third layer. This can minimize a distance between a region where the chip is mounted and a region where the bridge substrate is disposed. Accordingly, the embodiment can minimize signal transmission loss between chips and utilize a fine circuit pattern of the bridge substrate to a maximum extent.

Furthermore, the embodiment can have the second layer 112 in which the first cavity C1 is formed composed of multiple layers. This can minimize signal transmission loss between chips connected through the bridge substrate by utilizing more fine circuits of the bridge substrate, and utilize the fine circuit pattern of the bridge substrate to the maximum extent.

The first insulating layer 110 allows a relatively fine circuit layer and via to be formed compared to the second insulating layer 120. For example, when the first insulating layer 110 includes ABF, a width of the circuit layer or via formed in the first insulating layer 110 may be smaller than a width of the circuit layer or via formed in the second insulating layer 120.

In addition, a number of terminals in processor chips has been increasing recently. Accordingly, in the embodiment, a pitch of mounting pads on which the chip is mounted can be minimized, so that the first insulating layer 110 includes an insulating material such as ABF or PID.

However, the embodiment configures the first insulating layer 110 using ABF, which has excellent processability and is advantageous in CTE matching with the insulating material forming the second insulating layer 120.

Each of the first to third layers 111, 112, and 113 of the first insulating layer 110 may have a range of 8 μm to 35 μm. Each of the first to third layers 111, 112, and 113 of the first insulating layer 110 may have a thickness in a range of 10 μm to 30 μm. Each of the first to third layers 111, 112, and 113 of the first insulating layer 110 may have a thickness in a range of 11 μm to 20 μm. If the thickness of each of the first to third layers 111, 112, and 113 of the first insulating layer 110 is less than 8 μm, the circuit layer formed on the first insulating layer 110 may not be stably protected. If the thickness of each of the first to third layers 111, 112, and 113 of the first insulating layer 110 exceeds 35 μm, it may be difficult to miniaturize the circuit layer or via formed at the first insulating layer 110, and further, a thickness of the circuit board may increase.

The first layer 111 of the first insulating layer 110 is disposed on the second insulating layer 120. The first layer 111 of the first insulating layer 110 can fill at least a portion of the second cavity C2 and the third cavity C3 of the second insulating layer 120.

The second layer 112 of the first insulating layer 110 is disposed on the first layer 111 of the first insulating layer 110. The second layer 112 of the first insulating layer 110 can include a first cavity C1. The first cavity C1 can penetrate the second layer 112 of the first insulating layer 110. The first cavity C1 can provide a space in which a bridge substrate 200 is disposed within the first insulating layer 110. For example, the first cavity C1 may provide a space for embedding the bridge substrate 200 within the first insulating layer 110.

A width of the first cavity C1 may be larger than a width of the bridge substrate 200. At this time, an upper width and a lower width of the first cavity C1 may be different. For example, a lower width of the first cavity C1 may be smaller than an upper width of the first cavity C1. In addition, the width of the first cavity C1 described below may mean the lower width of the first cavity C1.

The width of the first cavity C1 may be 105% to 180% of the width of the bridge substrate 200. The width of the first cavity C1 may be 110% to 170% of the width of the bridge substrate 200. The width of the first cavity C1 may be 112% to 160% of the width of the bridge substrate 200. If the width of the first cavity C1 is smaller than 105% of the width of the bridge substrate 200, a problem may occur in which the bridge substrate 200 is not stably protected within the first cavity C1 due to a processing error in a process of forming the first cavity C1. In addition, if the width of the first cavity C1 is smaller than 105% of the width of the bridge substrate 200, stress may be concentrated at an edge region of an inner wall of the first cavity C1 in a process environment or an use environment of the circuit board, and a problem may occur in which the stress is transmitted to the bridge substrate 200. If the width of the first cavity C1 is greater than 180% of the width of the bridge substrate 200, a size of the circuit board in the horizontal direction may increase.

The third layer 113 of the first insulating layer 110 may be disposed on the second layer 112 of the first insulating layer 110. The third layer 113 of the first insulating layer 110 may fill at least a portion of the first cavity C1 of the second layer 112 of the first insulating layer 110. For example, the third layer 113 of the first insulating layer 110 may be disposed on the second layer 112 of the first insulating layer 110 while surrounding a periphery of the bridge substrate 200 disposed in the first cavity C1.

The third insulating layer 121 may be disposed under the second insulating layer 120.

The third insulating layer 121 may have a symmetrical structure with the first insulating layer 110 based on the second insulating layer 120.

The third insulating layer 121 may include a first layer 122, a second layer 123, and a third layer 124, but is not limited thereto.

Meanwhile, each layer of the first insulating layer 110 may have a thickness smaller than a thickness of the second insulating layer 120.

For example, a difference between a thickness of each layer of the first insulating layer 110 and a thickness of the second insulating layer 120 may be 15 μm or more, or 20 μm or 25 μm or more.

The circuit board of the embodiment includes a circuit layer. The circuit layer may be disposed on a surface of the insulating layer of the circuit board. For example, the circuit board of the embodiment may include a plurality of circuit layers disposed on surfaces of a plurality of insulating layers.

The circuit layer includes a first circuit layer disposed on a first insulating layer 110.

For example, the first circuit layer includes a first-first circuit layer 131 disposed on a first layer 111 of the first insulating layer 110. In addition, the first circuit layer includes a first-second circuit layer 132 disposed on a second layer 112 of the first insulating layer 110. In addition, the first circuit layer includes a first-third circuit layer 133 disposed on a third layer 113 of the first insulating layer 110.

In addition, the circuit layer includes a second circuit layer disposed on a second insulating layer 120.

For example, the second circuit layer includes a second-first circuit layer 134 disposed on an upper surface of the second insulating layer 120. In addition, the second circuit layer includes a second-second insulating layer 135 disposed on a lower surface of the second insulating layer 120.

In addition, the circuit layer includes a third circuit layer disposed on a third insulating layer 121.

For example, the third circuit layer includes a third-first circuit layer 136 disposed on a first layer 122 of the third insulating layer 121. In addition, the third circuit layer includes a third-second circuit layer 137 disposed on a second layer 123 of the third insulating layer 121. In addition, the third circuit layer includes a third-third circuit layer 138 disposed on a third layer 124 of the third insulating layer 121.

Meanwhile, the first circuit layer includes a pad part 131a that overlaps the first cavity C1 in a vertical direction. The pad part 131a can be in direct contact with an inner wall of the first cavity C1. For example, the pad part 131a can have an upper surface exposed through the first cavity C1. The pad part 131a may be a part of the first-first circuit layer 131 of the first circuit layer. That is, the pad part 131a may mean a circuit layer that overlaps the first cavity C1 in the vertical direction among the first-first circuit layers 131.

The pad part 131a may be larger than the width of the first cavity C1. Accordingly, the pad part 131a may be divided into a plurality of regions.

For example, the pad part 131a may include a first portion 131a1 that does not overlap with the first cavity C1 in the thickness direction (specifically, does not overlap with a lower region of the first cavity in the thickness direction). An upper surface of the first portion 131a1 of the pad part 131a may not be exposed through the first cavity C1. Preferably, the first portion 131a1 of the pad part 131a may be covered with the second layer 112 of the first insulating layer 110.

In addition, the pad part 131a may include a second portion 131a2 and 131a3 that overlaps the first cavity C1 in the thickness direction. An upper surface of the second portion 131a2 and 131a3 of the pad part 131a may be exposed through the first cavity C1.

The pad part 131a may function as a laser stopper during a process of forming the first cavity C1.

In addition, the pad part 131a may function as a mounting pad for disposing the bridge substrate 200.

In addition, the pad part 131a may function as a heat dissipation pad for transferring heat generated from the bridge substrate 200.

Meanwhile, the second portion 131a2 and 131a3 of the pad part 131a may be divided into a plurality of portions. The second portion 131a2 and 131a3 of the pad part 131a may include a second-first portion 131a2 that does not overlap with at least one of an adhesive layer 500 and the bridge substrate 200 in the thickness direction. At this time, the second-first portion 131a2 is illustrated as being vertically overlapped with the adhesive layer 500 as a whole in the drawing, but is not limited thereto. Preferably, the second-first portion 131a2 means a part of the second portion that does not overlap with the bridge substrate 200 in the thickness direction. In addition, the second-first portion 131a2 may overlap with the adhesive layer 500 in the thickness direction, or may not overlap with the adhesive layer 500.

In addition, the second portion of the pad part 131a includes a second-second portion 131a3 that overlaps with the adhesive layer 500 and the bridge substrate 200 in the thickness direction. That is, the second-second portion 131a3 of the second portion of the pad part 131a provides a space where the bridge substrate 200 is actually disposed. In addition, the second-first portion 131a2 may function as a free space in a process of inserting or placing the bridge substrate 200 in the first cavity C1.

Meanwhile, the first circuit layer, the second circuit layer, and the third circuit layer may be formed of at least one metal material selected from gold (Au), silver (Ag), platinum (Pt), titanium (Ti), tin (Sn), copper (Cu), and zinc (Zn). The first circuit layer, the second circuit layer, and the third circuit layer may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the first circuit layer, the second circuit layer, and the third circuit layer may be formed of copper (Cu) which has high electrical conductivity and is relatively inexpensive.

The first circuit layer, the second circuit layer, and the third circuit layer can be manufactured using conventional manufacturing processes of printed circuit boards, such as additive process, subtractive process, MSAP (Modified Semi Additive Process), and SAP (Semi Additive Process), and a detailed description thereof is omitted herein.

The first circuit layer, the second circuit layer, and the third circuit layer can have a thickness in a range of 7 μm to 20 μm. For example, the first circuit layer, the second circuit layer, and the third circuit layer can have a thickness in a range of 9 μm to 17 μm. The first circuit layer, the second circuit layer, and the third circuit layer can have a thickness in a range of 10 μm to 13 μm. If the thickness of the first circuit layer, the second circuit layer, and the third circuit layer is less than 7 μm, resistance may increase, and thus electrical characteristics may deteriorate. In addition, if the thickness of the first circuit layer, the second circuit layer, and the third circuit layer is less than 7 μm, the warpage characteristics of the circuit board may deteriorate. In addition, if the thickness of the first circuit layer, the second circuit layer, and the third circuit layer exceeds 20 μm, it may be difficult to miniaturize the circuit layers. Accordingly, the circuit integration of the circuit board may deteriorate. Accordingly, the size of the circuit board may increase.

The first circuit layer, the second circuit layer, and the third circuit layer include pads and traces. The pads may include via pads connected to vias, core pads or BGA pads on which adhesive balls (to be described later) connected to the main board of the electronic device are disposed. In addition, the traces may mean long line-shaped wiring that transmits electrical signals while being connected to the pads. The pads (specifically, via pads) of the first circuit layer, the second circuit layer, and the third circuit layer may have a width in a range of 20 μm to 50 μm. The pads of the first circuit layer, the second circuit layer, and the third circuit layer may have a width in the range of 22 μm to 40 μm. The pads of the first circuit layer, the second circuit layer, and the third circuit layer may have a width in the range of 25 μm to 35 μm.

Meanwhile, the traces of the first circuit layer, the second circuit layer, and the third circuit layer may have a specific line width and a specific spacing. For example, the line width of the traces of the first circuit layer, the second circuit layer, and the third circuit layer may have a range of 6 μm to 20 μm. For example, the line width of the traces of the first circuit layer, the second circuit layer, and the third circuit layer may have a range of 7 μm to 15 μm. For example, the line width of the traces of the first circuit layer, the second circuit layer, and the third circuit layer may have a range of 8 μm to 12 μm. In addition, the spacing between the traces of the first circuit layer, the second circuit layer, and the third circuit layer may have a range of 6 μm to 20 μm. For example, the spacing between the traces of the first circuit layer, the second circuit layer, and the third circuit layer may have a range of 7 μm to 15 μm. For example, the spacing between the traces of the first circuit layer, the second circuit layer, and the third circuit layer may have a range of 8 μm to 12 μm.

Meanwhile, the first circuit layer, the second circuit layer, and the third circuit layer may have different thicknesses, widths, and spacings. For example, the first circuit layer and the third circuit layer are disposed on the first insulating layer 110 and the third insulating layer 121, which are the first insulating material. In addition, the second circuit layer is disposed on the second insulating layer 120, which is the second insulating material. Accordingly, the thickness, width, and spacing of the first circuit layer and the third circuit layer may be smaller than the thickness, width, and spacing of the second circuit layer, but are not limited thereto.

For example, the thickness, width, and spacing of the first circuit layer may decrease as a distance from the second circuit layer increases.

For example, the thickness, width, and spacing of the first-third circuit layer 133 among the first circuit layers may be the smallest. This means that the first-third circuit layer 133 functions as a pad connected to the processor chip, and therefore must have a specification corresponding to terminals of the processor chip. In addition, he first-third circuit layer 133 requires integration. Accordingly, the embodiment allows the thickness, width, and spacing of the first-third circuit layer 133 among the first circuit layers to be the smallest.

In addition, the thickness, width, and spacing of the first-first circuit layer 131 among the first circuit layers may be the largest. For example, the thickness, width, and spacing of the first-first circuit layer 131 may correspond to the thickness, width, and spacing of the second circuit layer.

In addition, the thickness, width, and spacing of the first-second circuit layer 132 of the first circuit layer may be smaller than that of the first-first circuit layer 131 and larger than that of the first-third circuit layer 133. Accordingly, the embodiment minimizes signal transmission loss caused by differences in circuit layer specifications through changes in the thickness, width, and spacing of each layer of the first circuit layer.

Meanwhile, the third circuit layer is connected to the main board of the electronic device. Accordingly, the third circuit layer may have a specification corresponding to specifications of the main board of the electronic device (e.g., a number of pads, a spacing between pads, etc.).

Meanwhile, the circuit board of the embodiment includes a via. The via penetrates at least one insulating layer. Accordingly, the via may also be referred to as a through electrode. The via may penetrate one insulating layer. Differently, the via may commonly penetrate at least two or more insulating layers.

The via includes a first via penetrating the first insulating layer 110.

The first via includes a first-first via 141 penetrating the first layer 111 of the first insulating layer 110. The first via includes a first-second via 142 penetrating the second layer 112 of the first insulating layer 110. The first via includes a first-third via 143 penetrating the third layer 113 of the first insulating layer 110.

The via includes a second via 144 penetrating the second insulating layer 120.

In addition, the via includes a third via penetrating the third insulating layer 121.

The third via includes a third-first via 145 penetrating the first layer 122 of the third insulating layer 121. The third via includes a third-second via 146 penetrating the second layer 123 of the third insulating layer 121. The third via includes a third-third via 147 penetrating the third layer 124 of the third insulating layer 121.

Each of the first to third vias may have a width in a range of 10 μm to 60 μm. Each of the first to third vias may have a width in a range of 15 μm to 50 μm. Each of the first to third vias may have a width in a range of 20 μm to 40 μm. At this time, each of the first to third vias includes a first surface and a second surface opposite to the first surface. In addition, a width of the first surface is different from a width of the second surface. At this time, the width of each of the first to third vias may mean a width of a surface with a relatively large width among the first surface and the second surface.

At this time, the first to third vias may have different widths. In addition, for example, the second via 144 may have a larger width than the first via and the second via. In addition, the second via 144 may have a cross-sectional shape different from cross-sectional shapes of the first via and the second via, but is not limited thereto.

Meanwhile, the first via of the embodiment may include vias having different thicknesses or widths in a same layer.

For example, the first-first via 141 may include a first sub-via 141a and a second sub-via 141b depending on a location.

The first sub-via 141a of the first-first via 141 refers to a via connected to the second circuit layer 134 disposed on the upper surface of the second insulating layer 120.

The second sub-via 141b of the first-first via 141 is spaced apart from the first sub-via 141a of the first-first via 141 in the horizontal direction. The second sub-via 141b of the first-first via 141 is connected to the devices 300 and 400 inserted into the second insulating layer 120. For example, the second sub-via 141b of the first-first via 141 is connected to terminals 300 and 400 of the devices 300 and 400.

Accordingly, the first sub-via 141a and the second sub-via 141b of the first-first via 141 may have different widths or thicknesses.

For example, a width of the first sub-via 141a of the first-first via 141 may be larger than a width of the second sub-via 141b of the first-first via 141. That is, the second sub-via 141b of the first-first via 141 is connected to terminals 300 and 400 of the devices 300 and 400, and therefore must have a width or pitch corresponding to the specifications of the terminals 300 and 400. However, the first sub-via 141a of the first-first via 141 is connected to the second circuit layer. In addition, the first sub-via 141a of the first-first via 141 may have a width corresponding to the width of the second via 144 in order to minimize signal transmission loss.

Meanwhile, a thickness of the first sub-via 141a of the first-first via 141 may correspond to a thickness of the first layer 111 of the first insulating layer 110. In addition, a thickness of the second sub-via 141b of the first-first via 141 may be different from a thickness of the first sub-via 141a of the first-first via 141. For example, a thickness of the second sub-via 141b of the first-first via 141 may be different from a thickness of the first layer 111 of the first insulating layer 110.

For example, a position of an upper surface of the terminal 300 and 400 of the device 300 and 400 may be different from a position of an upper surface of the second circuit layer 134 disposed on the upper surface of the second insulating layer 120. For example, an upper surface of the terminal 300 and 400 of the device 300 and 400 may be positioned higher than an upper surface of the second circuit layer 134 disposed on the upper surface of the second insulating layer 120, or may be positioned lower than an upper surface of the second circuit layer 134.

Therefore, in one example, a thickness of the first sub-via 141a of the first-first via 141 may be greater than the thickness of the second sub-via 141b of the first-first via 141. In addition, in another example, a thickness of the first sub-via 141a of the first-first via 141 may be smaller than a thickness of the second sub-via 141b of the first-first via 141.

Meanwhile, the first-third via 143 may include first to third sub-vias 143a, 143b, and 143c depending on a location. The first sub-via 143a of the first-third via 143 may mean a via that overlaps the bridge substrate 200 in a vertical direction. For example, the first sub-via 143a of the first-third via 143 means a via directly connected to the bridge substrate 200.

The second sub-via 143b of the first-third via 143 means a via connected to a mounting pad (not shown) connected to a processor chip.

The third sub-via 143c of the first-third via 143 means a via connected to a mounting pad (not shown) connected to a memory chip.

In addition, the first sub-via 143a of the first-third via 143 may have a different thickness from the second and third sub-vias 143b and 143c of the first-third via 143. In addition, the first sub-via 143a of the first-third via 143 may have a different width from the second and third sub-vias 143b and 143c of the first-third via 143.

In addition, the second sub-via 143b of the first-third via 143 requires miniaturization for connection with a processor chip mounted on a substrate. Therefore, the second sub-via 143b of the first-third via 143 may have a smaller width than the third sub-via 143c of the first-third via 143.

Meanwhile, the third sub-via 143c of the first-third via 143 may have a larger width than the first and second sub-vias 143a and 143b of the first-third via 143.

In addition, the first sub-via 143a of the first-third via 143 may have a smaller width than the second sub-via 143b of the first-third via 143. This can reduce the signal transmission length connecting the process chips mounted on the substrate, thereby reducing signal loss when transmitting signals between chips.

As described above, in the embodiment, the first vias disposed in the first insulating layer 110 have different thicknesses or widths depending on their positions or functions. In the embodiment, the signal transmission loss occurring in the circuit board connected to the processor chip, the device 300 and 400, and the bridge substrate 200 can be minimized, and thus the communication performance can be improved.

Meanwhile, the vias may be formed by forming a through hole penetrating each insulating layer and filling the inside of the formed through hole with a conductive material.

The through hole may be formed by any one of mechanical, laser, and chemical processing methods. The through hole can be formed using any one of the mechanical processing methods of milling, drilling, and routing. In addition, the through hole can be formed using any one of the laser processing methods of UV or CO2. In addition, the through hole can be formed using the chemical processing method using a chemical agent including amino silane, ketones, etc.

When the through hole is formed, the through hole can be filled with a conductive material to form each via. The metal material forming the via can be any one material selected from copper (Cu), silver (Ag), tin (Sn), gold (Au), nickel (Ni), and palladium (Pd). In addition, the conductive material filling can use any one of the electroless plating, electrolytic plating, screen printing, sputtering, evaporation, ink-jetting, and dispensing, or a combination thereof.

Meanwhile, the circuit board of the embodiment provides a mounting region in which at least two chips of different types are mounted. In addition, the circuit board of the embodiment provides an embedded region in which at least one passive device is embedded. The mounting region may mean a chip placement region provided at an outside of the circuit board. In addition, the embedded region may mean a chip placement region provided at an inside of the circuit board.

The circuit board may transmit and receive signals acquired or processed by at least two processor chips or a processor chip and a memory chip. At this time, a connection between the at least two processor chips or the processor chip and the memory chips is made in the bridge substrate 200.

That is, the circuit board provides a chip mounting region in which a plurality of first and second chips of different types can be mounted. At this time, the first and second chips may be first and second processor chips that separate the application processor according to function.

For example, the circuit board of the embodiment provides a first mounting region in which a first processor chip is mounted. In addition, the circuit board of the embodiment provides a second mounting region in which a second processor chip is mounted. At this time, the first processor chip may be any one of an application processor (AP) chip such as a central processor (e.g., a CPU), a graphic processor (e.g., a GPU), a digital signal processor, an encryption processor, a microprocessor, a microcontroller, etc. The second processor chip may be a different type of processor chip from the first processor chip among the application processor (AP) chips such as a central processor (e.g., a CPU), a graphic processor (e.g., a GPU), a digital signal processor, an encryption processor, a microprocessor, a microcontroller, etc. For example, the first processor chip may be a central processor chip, and the second processor chip may be a graphic processor chip. That is, the circuit board of the embodiment may be a circuit board for separating application processors by function and for die splitting at least two processor chips separated by function.

Meanwhile, recently, as the functions required for application processors increase, there is a demand for separate processor chips for each function and a circuit board on which these processor chips can be mounted. At this time, even when the application processor is divided into two processor chips for each function, the number of terminals (Input/Output) provided on each processor chip is increasing. At this time, unlike the case where all functions are processed by one application processor chip as in the comparative example, when the processor chip is divided into at least two, each processor chip must be electrically connected to each other to exchange signals.

At this time, when a separation distance between each processor chip is great, a fine pattern as in the embodiment may not be required. However, when a separation distance between each processor chip is great, the communication speed for mutual signal exchange can decrease. In addition, when the separation distance between each processor chip increases, power consumption required for communication increases. In addition, when the separation distance between each processor chip is great, the length of the trace connecting each processor chip also increases, which causes vulnerability to noise and increases signal transmission loss.

That is, the separation distance between the processor chips must be 150 μm or less for reliability. For example, the separation distance between the processor chips must be less than 120 μm for reliability. For example, the separation distance between the processor chips should be less than 100 μm for reliability.

Accordingly, in order to connect all the wiring between the first processor chip and the second processor chip within the limited space as described above, the circuit pattern is required to be refined to a specific line width and a specific spacing or less.

In addition, Additionally, conventionally, there were N number of connection wires between the first processor chip and the second processor chip. And, if there are N number of connecting wires, a level of refinement of the circuit pattern within the limited space described above can be different from the embodiment.

On the other hand, due to recent 5G, Internet of Things (IOT), increased image quality, increased communication speed, etc., the number of terminals in the first processor chip and the second processor chip is gradually increasing. Accordingly, recently, the connection wires between the first processor chip and the second processor chip can be 2 times or more (2N), 3 times or more (3N), or 10 times or more (10N) that of the prior art.

Accordingly, in order to mount the first processor chip and the second processor chip on one circuit board while minimizing the separation distance between them and connect the first processor chip and the second processor chip to each other within a limited space, ultra-fineness of the circuit layers in the circuit board is required.

However, there is a limit to miniaturizing the circuit layers. Accordingly, the embodiment allows the bridge substrate 200 to be disposed on the first layer of the first insulating layer 110. In addition, the embodiment allows connection between at least two chips to be mounted on the circuit board to be made through the bridge substrate 200.

Accordingly, as described above, the width or thickness of the first sub-via 143a of the first-third via 143 may be different from the width or thickness of other sub-vias of the first-third via 143. This is because the thickness and width of the first sub-via 143a of the first-third via 143 are determined according to a height of the bridge substrate 200 and a width of wiring layers included in the bridge substrate 200.

For example, a height of an uppermost wiring layer of the bridge substrate 200 may be positioned lower than an upper surface of the first-second circuit layer 132. Alternatively, a height of an uppermost wiring layer of the bridge substrate 200 may be positioned higher than an upper surface of the first-second circuit layer 132. Accordingly, a thickness of the first sub-via 143a of the first-third via 143 may be greater than thicknesses of the other sub-vias, or may be smaller than thicknesses of the other sub-vias. However, in the embodiment, a thickness difference between the first sub-via 143a of the first-third via 143 and the other sub-vias of the first-third via 143 is minimized. Through this, the embodiment can improve the reliability of the circuit board. In this case, the uppermost wiring layer of the bridge substrate 200 may mean a circuit layer of the bridge substrate, or alternatively, may mean a pad layer of the bridge substrate.

This can be achieved by structural features of the bridge substrate 200 to be described later.

Meanwhile, the circuit board of the embodiment includes a first protective layer 151. The first protective layer 151 may be disposed on the first insulating layer 110.

In addition, the circuit board of the embodiment includes a second protective layer 152. The second protective layer 152 may be disposed under the third insulating layer 121.

Each of the first protective layer 151 and the second protective layer 152 includes at least one opening.

Meanwhile, the bridge substrate 200 is disposed in the first cavity C1 of the first insulating layer 110. That is, the bridge substrate 200 is embedded in the first insulating layer 110. Specifically, the bridge substrate 200 may be covered with the third layer 113 of the first insulating layer 110 while being disposed in the first cavity C1 formed in the second layer 112 of the first insulating layer 110.

The bridge substrate 200 is electrically connected to the first circuit layer and the first via formed in the first insulating layer 110.

For example, the bridge substrate 200 is connected to the first-third via 143 penetrating the third layer 113 of the first insulating layer 110. Preferably, the bridge substrate 200 is connected to the first sub-via 143a of the first-third via 143.

At this time, the first sub-via 143a of the first-third via 143 may be divided into a plurality of groups. For example, the first sub-via 143a of the first-third via 143 includes at least one first group of vias connected to the first processor chip. In addition, the first sub-via 143a of the first-third via 143 includes at least one second group of vias connected to the second processor chip. In addition, the bridge substrate 200 is connected to the first group of vias and the second group of vias of the first sub-via 143a of the first-third via 143. For example, the bridge substrate 200 electrically connects between the first group of vias and the second group of vias of the first sub-via 143a. Accordingly, the bridge substrate 200 connects between the first processor chip and the second processor chip. Specifically, the first processor chip includes a plurality of first terminals. In addition, the second processor chip includes a plurality of second terminals. At this time, at least one of the plurality of first terminals must be electrically connected to at least one of the plurality of second terminals. At this time, the embodiment electrically connects at least one of the plurality of first terminals and at least one of the plurality of second terminals using the bridge substrate 200.

The bridge substrate 200 can perform die-to-die interconnection between dies that electrically connect a plurality of processor chips mounted on a circuit board. The plurality of processor chips must be electrically connected to each other within a limited space. At this time, in order to connect the plurality of processor chips, a highly dense connection circuit is required within a limited space. Accordingly, in the embodiment, the bridge substrate 200 including a high-density circuit layer is disposed in the first cavity C1 of the first insulating layer 110. In addition, the embodiment electrically connects a plurality of processor chips mounted on the circuit board using the bridge substrate 200.

The bridge substrate 200 may include an ultra-fine pattern.

The bridge substrate 200 includes an insulating layer 210 and a circuit layer disposed on the insulating layer 210.

Referring to FIG. 6, the bridge substrate 200 may include one insulating layer, but is not limited thereto. For example, the bridge substrate 200 may include an insulating layer having a multilayer laminated structure.

Accordingly, the circuit layer of the bridge substrate 200 may include a first circuit layer 220a disposed on an upper surface of the insulating layer 210 and a second circuit layer 220b disposed on a lower surface of the insulating layer 210.

In addition, the bridge substrate 200 includes a via 230 penetrating the insulating layer 210. The via 230 of the bridge substrate 200 electrically connects the first circuit layer 220a and the second circuit layer 220b of the bridge substrate 200.

In addition, the bridge substrate 200 includes a protective layer disposed on the insulating layer 210. For example, the bridge substrate 200 includes a first protective layer 240a disposed on the upper surface of the insulating layer 210. In addition, the bridge substrate 200 includes a second protective layer 240b disposed on a lower surface of the insulating layer 210. The first protective layer 240a and the second protective layer 240b may be solder resists, but are not limited thereto.

The first protective layer 240a is disposed on the upper surface of the insulating layer 210. In addition, the first protective layer 240a includes an opening that overlaps at least a portion of the upper surface of the first circuit layer 220a in the thickness direction. For example, the first protective layer 240a may include a first opening overlapping the first circuit layer 220a connected to the first group of vias among the first sub-vias 143a in the thickness direction. In addition, the first protective layer 240a may include a second opening overlapping the first circuit layer 220a connected to the second group of vias among the first sub-vias 143a in the thickness direction.

In addition, the first circuit layer 220a overlapping the second opening of the first protective layer 240a in the thickness direction may function as a second pad layer connected to the second group of vias among the first sub-vias 143a.

The second protective layer 240b is disposed on the lower surface of the insulating layer 210. At this time, the second protective layer 240b does not include an opening. For example, the second protective layer 240b is disposed to entirely cover a side surface and a lower surface of the second circuit layer 220b of the bridge substrate 200.

At this time, the insulating layer 210, the first circuit layer 220a, and the second circuit layer 220b constituting the bridge substrate 200 may be referred to as a redistribution layer (RDL).

In addition, the redistribution layer (RDL) may include the first protective layer 240a and the second protective layer 240b.

The insulating layer 210 of the bridge substrate 200 may include an organic material. The insulating layer 210 of the bridge substrate 200 may include an insulating material different from the first insulating layer 110, the second insulating layer 120, and the third insulating layer 121. For example, the bridge substrate 200 may include an insulating material having excellent processability and elasticity. For example, the insulating layer 210 of the bridge substrate 200 may include polyimide (PI).

At this time, the insulating layer of a general bridge substrate is formed of a silicon material. Differently, the bridge substrate 200 of the embodiment includes polyimide (PI).

Accordingly, the embodiment allows the insulating layer 210 of the bridge substrate 200 to have a CTE similar to that of the first insulating layer 210 of the circuit board, thereby minimizing the stress applied to the bridge substrate 200. Through this, the embodiment allows the physical reliability and electrical reliability of the bridge substrate 200 to be improved.

In addition, the embodiment can reduce a cost of the bridge substrate 200 by changing the material of the insulating layer 210 applied to the bridge substrate 200 to polyimide, which is cheaper than the silicon substrate.

At this time, an alignment state between a first pad layer of the first circuit layer 220a of the bridge substrate 200 and the first group of vias of the first sub-via 143a of the first-third via 143 greatly affects the product reliability of the circuit board and the semiconductor package. In addition, an alignment state between a second pad layer of the first circuit layer 220a of the bridge substrate 200 and the second group of vias of the first sub-via 143a of the first-third via 143 greatly affects the product reliability of the circuit board and the semiconductor package. Accordingly, the embodiment uses polyimide (PI) having transparent properties as the insulating layer of the bridge substrate 200. By this, the embodiment can improve an alignment between the first and second pad layers of the bridge substrate 200 and the first sub-via 143a of the first-third via 143.

In addition, the embodiment can stably protect the bridge substrate (200) through CTE matching from stress generated during thermal deformation of the first insulating layer 110. Through this, the embodiment can stably make electrical connections between a plurality of semiconductor devices by the bridge substrate 200 and can stably operate a plurality of semiconductor devices.

That is, conventionally, the insulating layer of the bridge substrate is formed of a silicon material. At this time, the silicon has a large CTE difference from the insulating layer constituting the first insulating layer 110. Furthermore, the silicon has rigid characteristics. Accordingly, the conventional bridge substrate has a problem in that the bridge substrate including the silicon does not flow together when the first insulating layer 110 is thermally deformed. Accordingly, the conventional bridge substrate has reliability problems such as cracks during the thermal deformation.

In contrast, the embodiment allows the insulating layer 210 of the bridge substrate 200 to have a CTE similar to that of the first insulating layer 110 and to have flexible characteristics. Accordingly, the embodiment allows the bridge substrate 200 to flow during the thermal deformation of the first insulating layer 110, thereby solving reliability problems such as cracks of the bridge substrate 200.

In addition, the embodiment allows the insulating layer 210 to include polyimide (PI), so that a thickness of the bridge substrate 200 can be easily controlled. For example, in the conventional case including a silicon substrate, a process of polishing the silicon substrate must be performed in order to control a thickness of the bridge substrate. Accordingly, it was difficult to control a thickness of the bridge substrate to a desired thickness due to the difficulty of the process in the conventional bridge substrate. Furthermore, the conventional bridge substrate can connect pad parts provided on different layers using TSV (Through Silicon Via), but there is a problem that the processing difficulty of TSV is high and the manufacturing cost increases accordingly.

In contrast, the embodiment allows the insulating layer 210 of the bridge substrate 200 to include polyimide (PI), thereby making it easy to control the thickness of the bridge substrate 200. Furthermore, the embodiment can easily control the overall thickness of the bridge substrate 200 in accordance with a depth of the first cavity C1 formed in the first insulating layer 110. Accordingly, the embodiment can minimize a height difference between the first circuit layer 220a of the bridge substrate 200 and the first-second circuit layer 132 disposed on the second layer 112 of the first insulating layer 110. Accordingly, the embodiment can improve product reliability.

Furthermore, the embodiment can facilitate electrical connection between pad layers provided in different layers by including an organic material in the insulating layer 210 of the bridge substrate 200. For example, the embodiment forms vias penetrating the insulating layer 210 of the bridge substrate 200, and electrically connects pad layers provided in different layers through the vias. Through this, the embodiment can stably supply power to a semiconductor device by using the pad layers provided on upper and lower sides of the bridge substrate 200, respectively.

In particular, a number of power terminals and communication terminals of semiconductor packages applied to servers and/or HPCs (High Performance Computers) is increasing significantly. Accordingly, in a case of a conventional bridge substrate including an inorganic material, it may be difficult to stably supply power to the bridge substrate and the semiconductor device due to a lack of the number of power supply lines and/or a limitation of the power intensity, and the semiconductor package may not operate stably due to a lack of power of the bridge substrate and/or the semiconductor device.

In contrast, the embodiment can provide a bridge substrate 200 including an organic insulating layer, and through this, a number of power supply lines can be increased or a power intensity can be increased. Accordingly, the embodiment can enable a stable power supply to the bridge substrate 200 and/or the semiconductor device, and further, can prevent a drop in the power supplied to the bridge substrate and/or the semiconductor device through decoupling of a capacitor function.

Meanwhile, referring to FIG. 5, the bridge substrate 200 of the second embodiment can further include a first pad layer 250a and a second pad layer 250b. The first pad layer 250a of the bridge substrate 200 is disposed on the first circuit layer that vertically overlaps the first opening of the first protective layer 240a among the first circuit layers 220a of the bridge substrate 200. In addition, the second pad layer 250b of the bridge substrate 200 is disposed on the first circuit layer that vertically overlaps the second opening of the first protective layer 240a among the first circuit layers 220a of the bridge substrate 200. Accordingly, the bridge substrate of the second embodiment can further secure alignment between the first sub-via 143a of the first-third via 143 and the pad layers compared to the first embodiment. Meanwhile, the first pad layer 250a and the second pad layer 250b can also be referred to as bumps.

Meanwhile, referring to FIG. 6, the bridge substrate 200 of the third embodiment can have a multilayer structure. For example, the bridge substrate 200 can include a first insulating layer 210a, a second insulating layer 210b, and a third insulating layer 210c. In addition, the bridge substrate 200 may include a first circuit layer 220a disposed on the first insulating layer 210a. In addition, the bridge substrate 200 may include a second circuit layer 220b disposed between a lower surface of the first insulating layer 210a and an upper surface of the second insulating layer 210b. In addition, the bridge substrate 200 may include a third circuit layer 220c disposed between a lower surface of the second insulating layer 210b and an upper surface of the third insulating layer 210c. In addition, the bridge substrate 200 may include a fourth circuit layer 220d disposed on a lower surface of the third insulating layer 210c. In addition, the bridge substrate 200 of the third embodiment includes a first protective layer 240a disposed on an upper surface of the first insulating layer 210a. In addition, the bridge substrate 200 of the third embodiment includes a second protective layer 240b disposed on the lower surface of the third insulating layer 210c. In addition, the bridge substrate 200 of the third embodiment includes a first via 230a penetrating the first insulating layer 210a. In addition, the bridge substrate 200 of the third embodiment includes a second via 230b penetrating the second insulating layer 210b. In addition, the bridge substrate 200 of the third embodiment includes a third via 230c penetrating the third insulating layer 210c.

The following description will focus on the bridge substrate 200 of the first embodiment. However, the bridge substrate 200 may also have a structure as illustrated in FIGS. 5 and 6.

A slope of a side surface of the via 230 penetrating the insulating layer 210 of the bridge substrate 200 may be different from a slope of the side surface of the first via penetrating the first insulating layer 110.

Preferably, the slope of the side surface of the via 230 penetrating the insulating layer 210 of the bridge substrate 200 may be closer to a right angle than the slope of the side surface of the first via penetrating the first insulating layer 110.

Specifically, a difference between an upper width and a lower width of the via 230 penetrating the insulating layer 210 of the bridge substrate 200 of the embodiment may be smaller than a difference between an upper width and a lower width of the first via penetrating the first insulating layer 110.

For example, the lower width of the via 230 penetrating the insulating layer 210 of the bridge substrate 200 may have a range of 95% to 105% of the upper width of the via 230. For example, the lower width of the via 230 penetrating the insulating layer 210 of the bridge substrate 200 can satisfy a range of 96% to 104% of the upper width of the via 230. For example, the lower width of the via 230 penetrating the insulating layer 210 of the bridge substrate 200 can satisfy a range of 97% to 103% of the upper width of the via 230. Accordingly, the embodiment can improve the electrical characteristics of the bridge substrate 200.

Meanwhile, a reason why the slope of the side surface of the via 230 of the bridge substrate 200 can be substantially close to a right angle is because the insulating layer 210 of the bridge substrate 200 includes polyimide (PI). That is, the embodiment can form a via hole penetrating the insulating layer 210 of the bridge substrate 200 by using a UV laser so that the insulating layer 210 includes polyimide (PI). Accordingly, a slope of an inner wall of the via 230 penetrating the insulating layer 210 can be close to a right angle with respect to an upper or lower surface of the insulating layer 210.

Meanwhile, referring to FIGS. 7 and 8, the first circuit layer 220a, the second circuit layer 220b, and the via 230a of the bridge substrate 200 of the embodiment can have a multi-layer structure.

Specifically, the first circuit layer 220a of the bridge substrate 200 can include a first metal layer 220a1 and a second metal layer 220a2. In addition, the second circuit layer 220b of the bridge substrate 200 may also include a first metal layer 220b1 and a second metal layer 220b2 corresponding to the first circuit layer 220a. In addition, the via 230a of the bridge substrate 200 may also include a first metal layer 230a1 and a second metal layer 230a2 corresponding to the first circuit layer 220a and the second circuit layer 220b.

Hereinafter, the first metal layer 220a1 and the second metal layer 220a2 of the first circuit layer 220a will be described. The first metal layer 220a1 and 230a1 and the second metal layer 220b2 and 230a2 of the second circuit layer 220b and the via 230a may be formed to correspond to the first metal layer 220a1 and the second metal layer 220a2 of the first circuit layer 220a described below.

The first metal layer 220a1 of the first circuit layer 220a may be a metal layer formed through sputtering. The first metal layer 220a1 may be a seed layer. The first metal layer 220a1 may have a one-layer structure, or alternatively, may have a two-layer structure.

When the first metal layer 220a1 has a one-layer structure, the first metal layer 220a1 may include only a first layer including at least one of nickel (Ni) and chromium (Cr). In addition, when the first metal layer 220a1 has a two-layer structure, the first metal layer 220a1 may further include a second layer including copper (Cu) on the first layer. Hereinafter, the first metal layer 220a1 will be described as including a first layer and a second layer. However, the embodiment is not limited thereto.

The first layer of the first metal layer 220a includes at least one of nickel (Ni) and chromium (Cr) formed through a sputtering process. In addition, the second layer of the first metal layer 220a may be formed by sputtering a metal including copper (Cu) on the first layer of the first metal layer 220a.

The first layer of the first metal layer 220a may have a thickness of 0.01 μm to 0.15 μm. For example, the first layer of the first metal layer 220a may have a thickness of 0.03 μm to 0.14 μm. For example, the first layer of the first metal layer 220a may have a thickness of 0.05 μm to 0.12 μm. If the first layer of the first metal layer 220a is smaller than 0.01 μm, the first metal layer 220a may not function as a seed layer. In addition, if the first layer of the first metal layer 220a is smaller than 0.01 μm, the adhesion between the first metal layer 220a and the second metal layer 220b may not be secured.

In addition, if the thickness of the first layer of the first metal layer 220a1 is larger than 0.15 μm, the line width and spacing of the first circuit layer 220a of the bridge substrate 200 may increase. For example, if the thickness of the first layer of the first metal layer 220a1 is larger than 0.15 μm, it may be difficult to provide the first circuit layer 220a of the bridge substrate 200 in an ultra-fine pattern.

The second layer of the first metal layer 220a1 may have a thickness of

0.1 μm to 0.35 μm. For example, the second layer of the first metal layer 220a1 may have a thickness of 0.12 μm to 0.34 μm. For example, the second layer of the first metal layer 220a1 may have a thickness of 0.15 μm to 0.33 μm.

Meanwhile, a total thickness including the first layer and the second layer of the first metal layer 220a1 may be 0.5 μm or less. Preferably, a total thickness including the first layer and the second layer of the first metal layer 220a1 may be 0.4 μm or less. More preferably, a total thickness including the first layer and the second layer of the first metal layer 220a1 may be 0.3 μm or less. If the total thickness including the first layer and the second layer of the first metal layer 220a1 exceeds 0.5 μm, it may be difficult to miniaturize the first circuit layer 220a. Specifically, a process of forming the first circuit layer 220a of the bridge substrate 200 includes a seed layer removal process for removing the first metal layer 220a1. At this time, as the thickness of the first metal layer 220a1 increases, an etching amount in the seed layer process increases, and thus it may be difficult to fine the first circuit layer 220a of the bridge substrate 200.

The first metal layer 220a1 of the embodiment is formed by a sputtering process, and miniaturization of the first circuit layer 220a of the bridge substrate 200 may be possible.

The second metal layer 220a2 may be an electroplated layer formed by electroplating the first metal layer 220a1 as a seed layer. The second metal layer 220a2 may have a thickness in a range of 2 μm to 12 μm. The second metal layer 220a2 may have a thickness in a range of 3 μm to 11 μm. The second metal layer 220a2 may have a thickness in a range of 4 μm to 10 μm.

If the thickness of the second metal layer 220a2 is less than 2 μm, the second metal layer 220a2 may also be etched in the seed layer etching process, and thus, it may be difficult to normally implement the first circuit layer 220a of the bridge substrate 200. If the thickness of the second metal layer 220a2 is greater than 12 μm, it may be difficult to miniaturize the first circuit layer 220a of the bridge substrate 200.

In addition, the first metal layer 230a1 of the via 230a may be formed of a different metal layer from the first metal layer 220a1 and 220b1 of the first circuit layer 200a or the second circuit layer 220b. The first metal layer 230a1 of the via 230a may include palladium (Pd), which is a different metal from the first metal layer 220a1 and 220b1 of the first circuit layer 220a or the second circuit layer 220b.

A total thickness of the first circuit layer 220a having the layer structure as described above may have a thickness in a range of 3 μm to 13 μm. A total thickness of the first circuit layer 220a having the layer structure as described above may have a thickness in a range of 4 μm to 12 μm. A total thickness of the first circuit layer 220a having the layer structure as described above may have a thickness in a range of 5 μm to 11 μm. If the thickness of the first circuit layer 220a is less than 5 μm, the resistance of the first circuit layer 220a increases, and reliability may be reduced in connection with the first and second processor chips. If the thickness of the first circuit layer 220a exceeds 11 μm, it may be difficult to implement a fine pattern required in the bridge substrate 200.

Accordingly, the first circuit layer 220a may be an ultra-fine pattern. For example, the first circuit layer 220a may have a line width of 5 μm or less. For example, the first circuit layer 220a may have a line width of 3 μm or less. For example, the first circuit layer 220a may have a line width of 2 μm or less. The first circuit layer 220a may have a spacing of 5 μm or less. The spacing may mean a spacing between traces of the first circuit layer 220a disposed on a same layer. For example, the first circuit layer 220a may have a spacing of 3 μm or less. For example, the first circuit layer 220a may have a spacing of 2 μm or less.

Preferably, the first circuit layer 220a may have a line width of 1 μm to 5 μm. The first circuit layer 220a may have a line width of 1.2 μm to 3 μm. The first circuit layer 220a may have a line width of 1.5 μm to 2 μm. If the line width of the first circuit layer 220a is smaller than 1 μm, the resistance of the first circuit layer 220a increases, and normal communication with the processor chip may be difficult due to this. If the line width of the first circuit layer 220a is larger than 5 μm, it may be difficult to implement a bridge substrate 200 for connection between a plurality of processor chips in a limited space. For example, if the line width of the first circuit layer 220a is larger than 6 μm, it may be difficult to place a bridge substrate 200 including a trace for connection between a plurality of processor chips in a first cavity C1 formed in a limited space.

Meanwhile, the second circuit layer 220b of the bridge substrate 200 may also include a first metal layer 220b1 and a second metal layer 220b2 having a structure corresponding to the first circuit layer 220a.

In addition, the via 230a of the bridge substrate 200 may also include a first metal layer 230a1 and a second metal layer 230a2 having structures corresponding to the first circuit layer 220a and the second circuit layer 220b.

Meanwhile, the second metal layer 230a2 of the via 230a may have different structures depending on the embodiment.

For example, as illustrated in FIG. 7, the second metal layer 230a2 of the via 230a may be disposed to entirely fill a through hole penetrating the insulating layer 210 of the bridge substrate 200.

As another example, as illustrated in FIG. 8, the second metal layer 220a2 of the via 230a may be disposed to partially fill a through hole penetrating the insulating layer 210 of the bridge substrate 200.

Meanwhile, the circuit board of the embodiment includes an adhesive layer 500 disposed on the lower surface of the second protective layer 240b of the bridge substrate 200. The adhesive layer 500 may be disposed on the pad part 131a exposed through the first cavity C1.

The adhesive layer 500 can provide bonding force so that the bridge substrate 200 is stably fixed or mounted in the first cavity C1.

Meanwhile, the circuit board of the embodiment may further include a device 300 and 400 disposed in the second cavity C2 and the third cavity C3 of the second insulating layer 120. The device 300 and 400 may be a passive device, but is not limited thereto. For example, the circuit board of the embodiment may also have an active device embedded therein.

For example, the circuit board may include a first device 300 disposed in the second cavity C2. The first device 300 may be an integrated passive device (IPD). The first device 300 includes a terminal 310. The terminal 310 of the first device 300 may be electrically connected to the second sub-via 141b of the first-first via 141 penetrating the first layer 111 of the first insulating layer 110.

For example, the circuit board may include a second device 400 disposed in the third cavity C3. The second device 400 may be a multilayer ceramic capacitor (MLCC), but is not limited thereto. The second device 400 includes a terminal 410. For example, when the second device 400 is a multilayer ceramic capacitor, the terminal of the second device 400 may include a plurality of terminals 411, 412, and 413. For example, the second device 400 may be a 3-terminal MLCC.

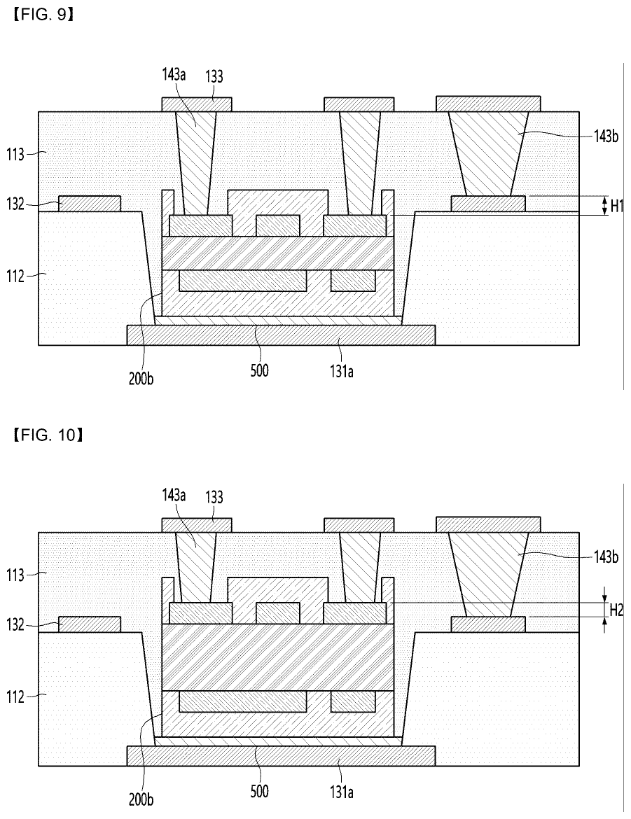

FIG. 9 is a cross-sectional view explaining a step between a first-second circuit layer and a pad layer of a bridge substrate according to a first embodiment, and FIG. 10 is a view explaining a step between a first-second circuit layer and a pad layer of a bridge substrate according to a second embodiment.

Referring to FIG. 9, the bridge substrate 200a in the first embodiment is disposed in the first cavity C1 of the second layer 112 of the first insulating layer 110.

At this time, it may be difficult to exactly match a thickness of the second layer 112 of the first insulating layer 110 corresponding to the depth of the first cavity C1 and a thickness of the bridge substrate 200a.

Accordingly, in the embodiment, the insulating layer 210 constituting the bridge substrate 200a is formed of polyimide (PI), thereby making it possible to easily control a thickness of the bridge substrate 200a.

Therefore, in the embodiment, a height difference H1 between an upper surface of a pad layer of the bridge substrate 200a and the first-second circuit layer 132 can be minimized.

The pad layer of the bridge substrate 200a may mean the first circuit layer 220a of the bridge substrate 200a in the first embodiment. In addition, the pad layer of the bridge substrate 200 may mean the first and second pad layers 250a and 250b protruding on the first circuit layer 220a in the second embodiment.

For example, the upper surface of the pad layer of the bridge substrate 200a may be positioned lower than the upper surface of the first-second circuit layer 132. For example, the upper surface of the pad layer of the bridge substrate 200a may be positioned lower than the upper surface of the first-second circuit layer 132 by a first height H1.

At this time, in the embodiment, the first height H1 can be easily controlled compared to a conventional bridge substrate including silicon, and thus the first height H1 can be set to 25 μm or less. For example, in the embodiment, the first height H1 is set to 20 μm or less. For example, in the embodiment, the first height H1 is set to 15 μm or less.

Preferably, in the embodiment, the first height H1 is set to be smaller than a difference in thickness between each layer of the first insulating layer 110 and the second insulating layer 120.

At this time, a difference in thickness or height occurs between the first sub-via 143a and the second sub-via 143b of the first-third via 143 penetrating the third layer 113 of the first insulating layer 110 by the difference in the first height H1. At this time, the first sub-via 143a and the second sub-via 143b of the first-third via 143 are each formed by filling the inside of the via hole with a metal material. At this time, if the first height H1 as described above increases, a difference in the size of the via hole constituting the first sub-via 143a and the via hole constituting the second sub-via 143b increases, and accordingly, a problem may occur in a plating property of a plating layer filling the inside thereof. In addition, as the reliability of the plating property decreases due to the difference in the size of the via hole, a positional misalignment of the first sub-via 143a and the second sub-via 143b may occur. In addition, the positional misalignment may act as a factor that deteriorates the electrical contact reliability between the circuit board and the bridge substrate 200a of the embodiment.

Accordingly, the embodiment makes it easy to control the thickness of the bridge substrate 200a by making the insulating layer 210 of the bridge substrate 200a include polyimide (PI). Accordingly, the embodiment can minimize the first height H1, and accordingly, the height or thickness difference between the first sub-via 143a of the first-third via 143 and the second sub-bridge substrate 200 can be minimized. Accordingly, the embodiment can improve contact reliability between the circuit board and the bridge substrate 200a, and further improve product reliability.

Meanwhile, referring to FIG. 10, the bridge substrate 200b in the second embodiment is disposed in the first cavity C1 of the second layer 112 of the first insulating layer 110.

The upper surface of the pad layer of the bridge substrate 200b in the second embodiment may be positioned higher than the upper surface of the first-second circuit layer 132. For example, the upper surface of the pad layer of the bridge substrate 200b may be positioned higher than the upper surface of the first-second circuit layer 132 by a second height H2. In addition, the embodiment sets the second height H2 to be 25 μm or less, 20 μm or less, or 15 μm or less.

The embodiment sets the first height H1 and the second height H2 to be less than the difference in thickness between each layer of the first insulating layer 110 and the second insulating layer 120. Through this, the embodiment can maintain the strength of the circuit board.

For example, in a case of the first embodiment of FIG. 9, the thickness of the substrate in a region where the bridge substrate is disposed can be secured, thereby improving the rigidity of the substrate. In the second embodiment of FIG. 10, it may be possible to implement a microcircuit of a pad part in contact with the chip mounting region.

In addition, the embodiment can improve chip mounting performance.

For example, when the first height H1 and the second height H2 are greater than the difference in the thickness of each layer of the first insulating layer 110 and the thickness of the second insulating layer 120, the height of the upper surface of the third layer 113 of the first insulating layer 110 can have a large difference for each region. Accordingly, the height difference of the mounting pad connected to the chip increases, and a defect may occur during chip mounting due to this.

In contrast, the embodiment can reduce a height deviation of the upper surface of the third layer 113 of the first insulating layer 110, thereby minimizing mounting defects during chip mounting.

The circuit board of the embodiment includes a first insulating layer and a second insulating layer. The second insulating layer may include a prepreg. Accordingly, the embodiment can maintain a rigidity of the circuit board to improve bending characteristics, thereby improving the product reliability. In addition, the first insulating layer includes ABF. Accordingly, the embodiment can reduce a size of a circuit layer and a via disposed on the first insulating layer. Specifically, the embodiment can form a circuit layer and a via of a fine pattern connected to a first processor chip and the second processor chip on the first insulating layer.

In addition, the first insulating layer includes a plurality of layers. In addition, a circuit layer and a via are disposed on each of the plurality of layers of the first insulating layer. At this time, the embodiment allows the circuit layer and via formed on the first insulating layer to gradually increase toward the second insulating layer. Accordingly, the embodiment can minimize signal transmission loss between the circuit layer and the via disposed on the first insulating layer and the circuit layer and the via disposed on the second insulating layer. Accordingly, the embodiment can improve communication characteristics of the circuit board.

In addition, the circuit board of the embodiment includes a bridge substrate embedded in the first insulating layer. The bridge substrate can be disposed in a first cavity formed in a second layer of the first insulating layer and covered with a third layer of the first insulating layer. In addition, the embodiment allows a pad layer included in the bridge substrate and the via penetrating the first insulating layer to be directly connected. Accordingly, the embodiment can minimize a signal transmission distance and further minimize the signal transmission loss.

In addition, the insulating layer of the bridge substrate of the embodiment has a CTE similar to that of the first insulating layer. Furthermore, an insulating layer of the bridge substrate of the embodiment has flexible characteristics. Specifically, the insulating layer of the bridge substrate can include polyimide (PI), which is an organic material. Accordingly, the embodiment can reduce a product unit cost compared to a bridge substrate including conventional silicon.

In addition, the bridge substrate of the embodiment includes a pad layer. The pad layer is directly connected to the first via disposed in the first insulating layer. At this time, an alignment state between the pad layer of the bridge substrate and the first via greatly affects the product reliability of the circuit board and the semiconductor package. At this time, in the embodiment, transparent polyimide is applied as the insulating layer of the bridge substrate. Accordingly, the embodiment can improve the alignment between the pad layer of the bridge substrate and the first via disposed on the first insulating layer. Accordingly, the embodiment can improve the overall product reliability.

In addition, the embodiment can stably protect the bridge substrate from stress generated during thermal deformation of the circuit board.

That is, in a conventional technology, the insulating layer of the bridge substrate includes silicon. Accordingly, the conventional bridge substrate has rigid characteristics due to the silicon. Accordingly, the stress generated when the circuit board was thermally deformed was directly transmitted to the bridge substrate. Accordingly, the conventional bridge substrate had reliability problems such as cracks.

In contrast, the insulating layer of the bridge substrate of the embodiment includes polyimide. Accordingly, a flow of the bridge substrate together with the first insulating layer can be achieved when the circuit board is thermally deformed. Accordingly, the embodiment can improve the physical reliability and electrical reliability of the bridge substrate.

Furthermore, the embodiment can easily control a thickness of the bridge substrate. For example, in a conventional case including silicon, a process of polishing a silicon substrate must be performed in order to control a thickness of the bridge substrate, and therefore, it was difficult to control the thickness of the bridge substrate to a desired thickness due to the difficulty of the process characteristics.

In contrast, the embodiment can easily control the entire thickness of the bridge substrate, and accordingly, the thickness of the bridge substrate can be easily controlled in accordance with a depth of a cavity formed in the first insulating layer. Accordingly, the embodiment can minimize a thickness difference between a first sub-via in direct contact with the bridge substrate and sub-vias excluding the first sub-via. Accordingly, the embodiment can improve the overall physical reliability and electrical reliability of the circuit board.

Hereinafter, a method for manufacturing a circuit board according to an embodiment will be described.

FIGS. 11 to 25 are drawings for explaining the circuit board of FIG. 2 in order of processes.

Referring to FIG. 11, the embodiment can proceed with a process for manufacturing an inner layer of a circuit board. To this end, the embodiment prepares a second insulating layer 120. Then, the embodiment forms a via hole penetrating the prepared second insulating layer 120. Thereafter, the embodiment forms a second via 144 filling the via hole of the second insulating layer 120. In addition, the embodiment can proceed with a process for forming a second circuit layer 134 and 135 on the upper and lower surfaces of the second insulating layer 120, respectively.

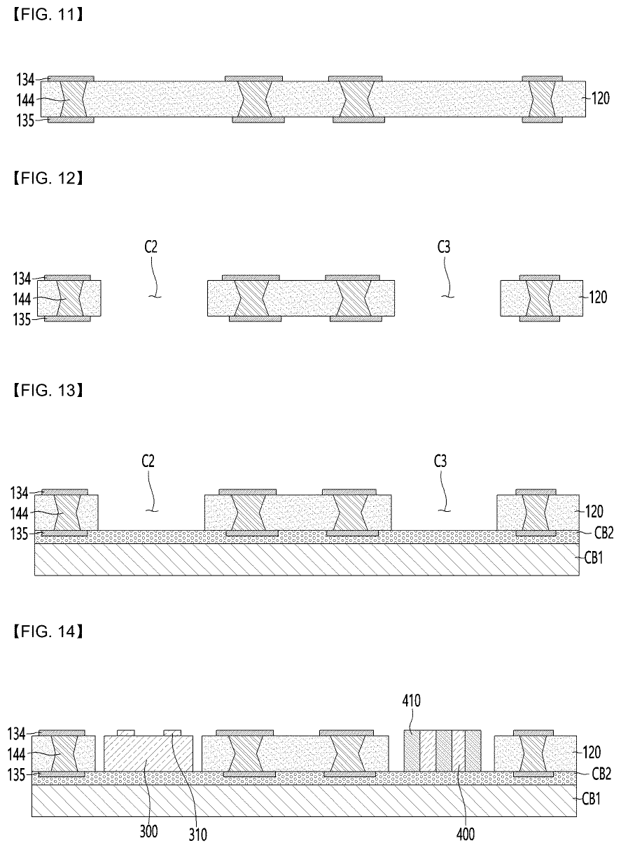

Referring to FIG. 12, the embodiment can proceed with a process for forming a second cavity C2 and a third cavity C3 in the second insulating layer 120. The second cavity C2 and the third cavity C3 may penetrate the upper surface and the lower surface of the second insulating layer 120, respectively. The second cavity C2 and the third cavity C3 may be formed to be spaced apart from each other in the horizontal direction within the second insulating layer 120.

Referring to FIG. 13, the embodiment may perform a process of arranging a carrier board on the lower surface of the second insulating layer 120. The carrier board may include a carrier insulating layer CB1 and a carrier adhesive layer CB2.

Referring to FIG. 14, the embodiment may perform a process of mounting the first device 300 in the second cavity C2 of the second insulating layer 120 using the carrier adhesive layer CB2 of the carrier board. In addition, the embodiment can perform a process of mounting the second device 400 in the third cavity C3 of the second insulating layer 120 using the carrier adhesive layer CB2 of the carrier board.

Referring to FIG. 15, the embodiment can perform a process of laminating a first layer 111 of the first insulating layer 110 on the second insulating layer 120. At this time, at least a part of the first layer 111 of the first insulating layer 110 can be positioned within the second cavity C2 and the third cavity C3 of the second insulating layer 120. For example, the first layer 111 of the first insulating layer 110 can be disposed to cover the first device 300 disposed in the second cavity C2. In addition, the first layer 111 of the first insulating layer 110 may be disposed to cover the second device 400 disposed in the third cavity C3.

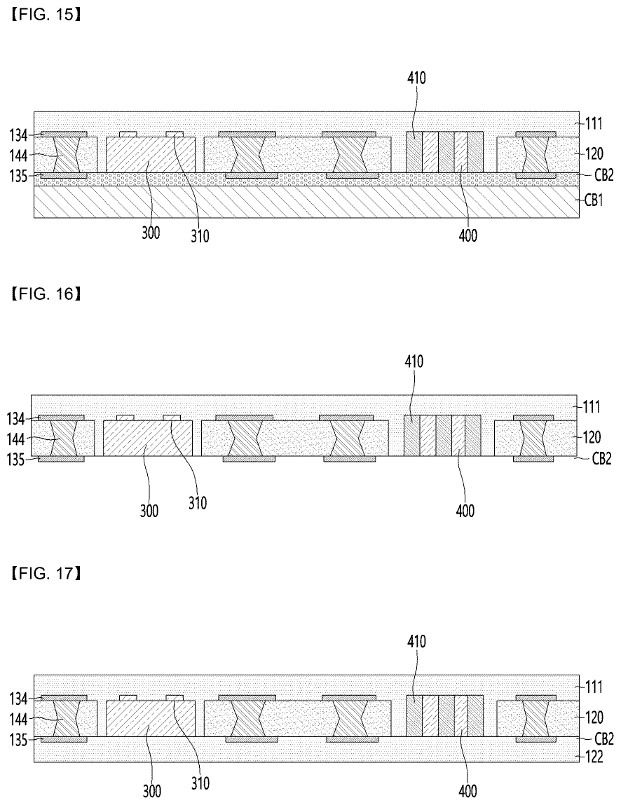

Referring to FIG. 16, the embodiment may perform a process of removing the carrier board disposed on the lower surface of the second insulating layer 120. As a result, the lower surface of the second insulating layer 120, the lower surface of the second circuit layer 135, the lower surface of the first device 300, and the lower surface of the second device 400 may be exposed.

Referring to FIG. 17, the embodiment may perform a process of laminating the first layer 122 of the third insulating layer 121 on the lower surface of the second insulating layer 120.

Referring to FIG. 18, the embodiment may perform a process of forming a first-first via 141 penetrating the first layer 111 of the first insulating layer 110 and a first-first circuit layer 131 on the upper surface of the first layer 111 of the first insulating layer 110.

In addition, the embodiment may perform a process of forming a third-first via 145 penetrating the first layer 122 of the third insulating layer 121 and a third-first circuit layer 136 on the lower surface of the first layer 122 of the third insulating layer 121.

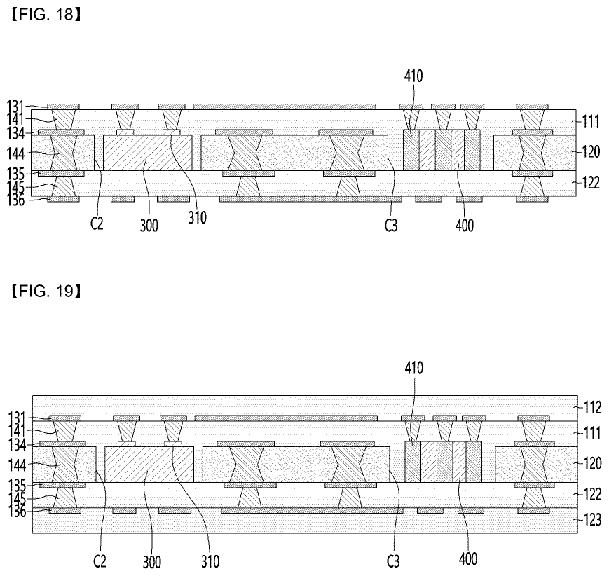

Referring to FIG. 19, the embodiment may perform a process of laminating a second layer 112 of the first insulating layer 110 on the first layer 111 of the first insulating layer 110. In addition, the embodiment may perform a process of laminating a second layer 123 of the third insulating layer 121 under the first layer 122 of the third insulating layer 121.

Referring to FIG. 20, the embodiment may perform a process of forming a first-second via 142 penetrating the second layer 112 of the first insulating layer 110 and a first-second circuit layer 132 on the upper surface of the second layer 112 of the first insulating layer 110.

In addition, the embodiment may perform a process of forming a third-second via 146 penetrating the second layer 123 of the third insulating layer 121 and a third-second circuit layer 137 on the lower surface of the second layer 123 of the third insulating layer 121.

At this time, the embodiment may perform a process of forming a first cavity C1 at a position corresponding to the pad part 131a of the first-first circuit layer 131 when forming a via hole corresponding to the first-second via 142.

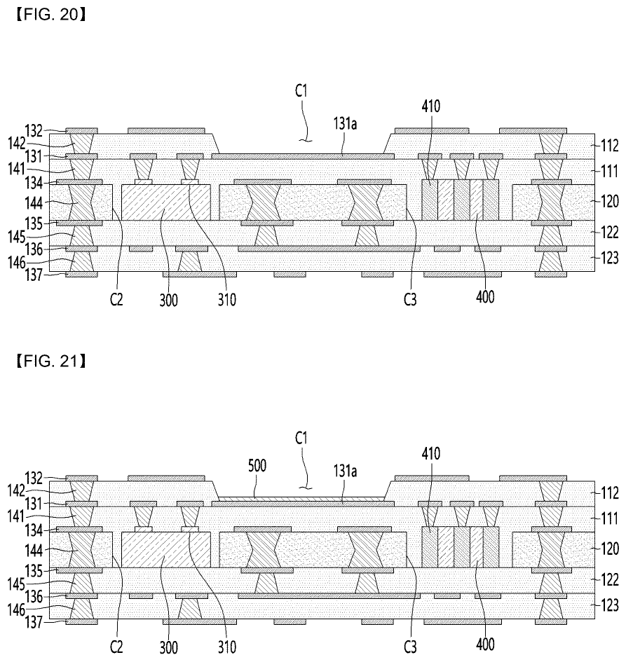

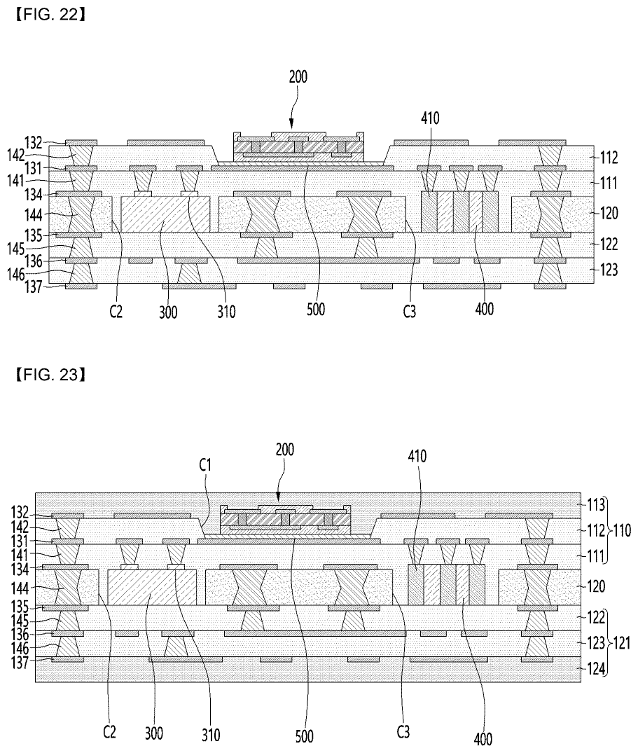

Referring to FIG. 21, the embodiment may perform a process of arranging an adhesive layer 500 on the pad part 131a exposed through the first cavity C1.

Referring to FIG. 22, the embodiment may perform a process of attaching a bridge substrate 200 on the adhesive layer 500.

Referring to FIG. 23, the embodiment may perform a process of forming a third layer 113 of the first insulating layer 110 on the second layer 112 of the first insulating layer 110. The third layer 113 of the first insulating layer 110 may be formed by filling the first cavity C1 formed in the second layer 112 of the first insulating layer 110. Accordingly, the bridge substrate 200 disposed in the first cavity C1 may be covered by the third layer 113 of the first insulating layer 110. Accordingly, the bridge substrate 200 may be embedded in the first insulating layer 110.

In addition, the embodiment may perform a process of forming the third layer 124 of the third insulating layer 121 under the second layer 123 of the third insulating layer 121.

Referring to FIG. 24, the embodiment may perform a process of forming a first-third via 143 penetrating the third layer 113 of the first insulating layer 110 and a first-third circuit layer 133 on the upper surface of the third layer 113 of the first insulating layer 110.

In addition, the embodiment may perform a process of forming a third-

third via 147 penetrating the third layer 124 of the third insulating layer 121 and a third-third circuit layer 138 on the lower surface of the third layer 124 of the third insulating layer 121.

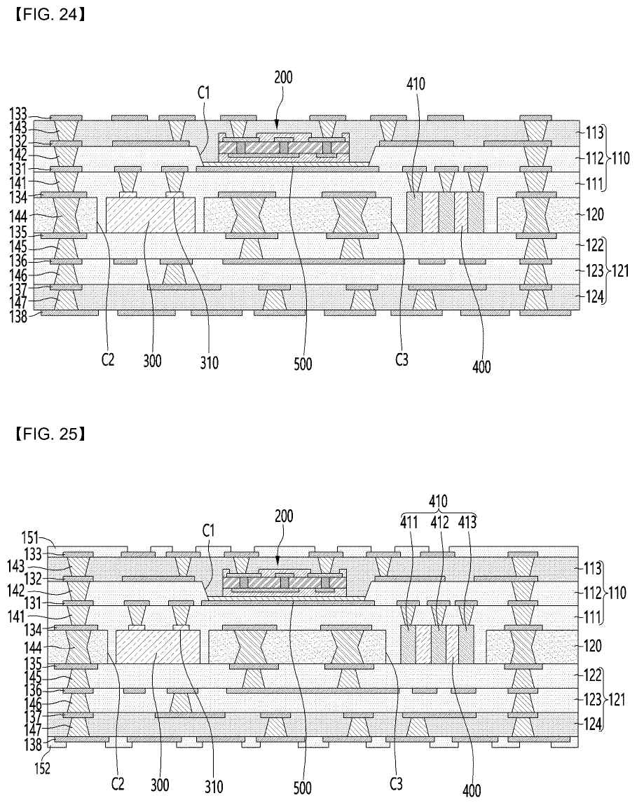

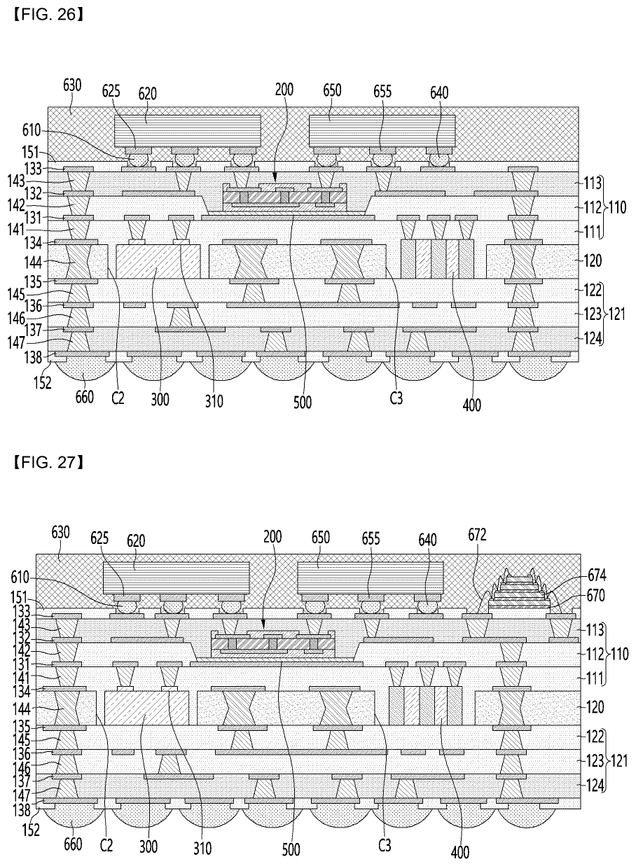

Referring to FIG. 25, the embodiment may perform a process of forming a first protective layer 151 on the third layer 113 of the first insulating layer 110.

In addition, the embodiment can proceed with a process of forming a second protective layer 152 under the third layer 124 of the third insulating layer 121.

FIG. 26 is a view showing a semiconductor package according to a first embodiment.

Referring to FIG. 26, in the embodiment, a structure may be provided in which a plurality of chips are mounted on the circuit board of FIG. 2.

To this end, the circuit board includes a first pad and a second pad. The first pad may be a part of the first-third circuit layer 133 disposed on an uppermost side of the first circuit layer of the circuit board. For example, the first pad may be a circuit layer of the first-third circuit layer 133 that overlaps the first opening of the first protective layer 151 in the thickness direction. In addition, the second pad may be a circuit layer of the first-third circuit layer 133 that overlaps the second opening of the first protective layer 151 in the thickness direction.

In addition, the semiconductor package may include a first adhesive part 610 disposed on the first pad of the circuit board. In addition, the semiconductor package may include a second adhesive part 640 disposed on the second pad.

The first adhesive part 610 and the second adhesive part 640 may have a same shape or, differently, may have different shapes.

For example, the first adhesive part 610 and the second adhesive part 640 may have a hexahedral shape. For example, cross-sections of the first adhesive part 610 and the second adhesive part 640 may include a square shape. The cross-sections of the first adhesive part 610 and the second adhesive part 640 may include a rectangle or a square. For example, the first adhesive part 610 and the second adhesive part 640 may include a spherical shape. For example, the cross-sections of the first adhesive part 610 and the second adhesive part 640 may include a circular shape or a semicircular shape. For example, the cross-sections of the first adhesive part 610 and the second adhesive part 640 may include a partially or entirely rounded shape. The cross-sectional shapes of the first adhesive part 610 and the second adhesive part 640 may be flat at one side and curved at other side. The first adhesive part 610 and the second adhesive part 640 may be solder balls, but are not limited thereto.

In an embodiment, a first chip 620 may be disposed on the first adhesive part 610. The first chip 620 may be a first processor chip. For example, the first chip 620 may be an application processor (AP) chip among a central processor (e.g., a CPU), a graphic processor (e.g., a GPU), a digital signal processor, an encryption processor, a microprocessor, and a microcontroller. A terminal 625 of the first chip 620 may be electrically connected to the first pad through the first adhesive part 610.

In addition, the embodiment may include a second chip 650 disposed on the second adhesive part 640. The second chip 650 may be a second processor chip. For example, the second chip 650 may be an application processor (AP) chip of a different type from the first chip 620 among a central processor (e.g., CPU), a graphic processor (e.g., GPU), a digital signal processor, an encryption processor, a microprocessor, and a microcontroller. A terminal 655 of the second chip 650 may be electrically connected to the second pad through the second adhesive part 640.

For example, the first chip 620 may be a central processor chip, and the second chip 650 may be a graphic processor chip, but is not limited thereto.

Meanwhile, the first chip 620 and the second chip 650 may be disposed on the circuit board with a first separation width. The first separation width may be 150 μm or less. For example, the first separation width may be 120 μm or less. For example, the first separation width may be 100 μm or less.

Preferably, the first separation width may have a range between 60 μm and 150 μm. Preferably, the first separation width may have a range between 70 μm and 120 μm. Preferably, the first separation width may have a range between 80 μm and 110 μm. If the first separation width is smaller than 60 μm, a problem may occur in the operational reliability of the first chip 620 or the second chip 650 due to interference between the first chip 620 and the second chip 650. If the first separation width is smaller than 60 μm, the bridge substrate 200 may not be disposed in a region corresponding to the first cavity C1 that overlaps the space corresponding to the first separation width in the thickness direction. If the first separation width is larger than 150 μm, signal transmission loss may increase as the distance between the first chip 620 and the second chip 650 increases. If the first separation width is larger than 150 μm, a volume of the bridge substrate 200 may increase, and further, a volume of the semiconductor package may increase.

The semiconductor package may include a molding layer 630. The molding layer 630 may be disposed to cover the first chip 620 and the second chip 650. For example, the molding layer 630 may be an EMC (Epoxy Mold Compound) formed to protect the mounted first chip 620 and the second chip 650, but is not limited thereto.

At this time, the molding layer 630 may have a low permittivity to enhance heat dissipation characteristics. For example, the permittivity (Dk) of the molding layer 630 may be 0.2 to 10. For example, the permittivity (Dk) of the molding layer 630 may be 0.5 to 8. For example, the permittivity (Dk) of the molding layer 630 may be 0.8 to 5. Accordingly, in the embodiment, the molding layer 630 is made to have a low permittivity, so as to increase the heat dissipation characteristics for heat generated from the first chip 620 and/or the second chip 650.

Meanwhile, the semiconductor package may include a third adhesive part 660 disposed at a lowermost side of the circuit board. The third adhesive part 660 may be disposed on the lower surface of the third-third circuit layer 138 exposed through the opening of the second protective layer 152.

FIG. 27 is a view showing a semiconductor package according to a second embodiment.

Referring to FIG. 27, the semiconductor package of the second embodiment further includes a memory chip mounting portion compared to the semiconductor package according to the first embodiment.

Specifically, the semiconductor package includes a memory chip 670 that is disposed side by side with the first chip 620 or the second chip 650 and spaced apart from the first chip 620 or the second chip 650. At this time, the memory chip 670 may have a multilayer structure with an adhesive layer 672 therebetween. In addition, the semiconductor package may include a connection member 674 that is connected to the memory chip 670. The connection member 674 may be a wire, but is not limited thereto.

Meanwhile, the semiconductor package according to the third embodiment may further include a second package disposed on the semiconductor package of the first embodiment. The second package may be a memory package including a memory chip.

To this end, a memory package including an interposer may be disposed on the semiconductor package of the first embodiment. Differently, the memory package may be disposed directly on the semiconductor package of the first embodiment.

Features, structures, effects, etc. described in the above embodiments are included in at least one embodiment, and it is not necessarily limited to only one embodiment. Furthermore, features, structures, effects, etc. illustrated in each embodiment can be combined or modified for other embodiments by those of ordinary skill in the art to which the embodiments belong. Accordingly, the contents related to such combinations and variations should be interpreted as being included in the scope of the embodiments.

In the above, the embodiment has been mainly described, but this is only an example and does not limit the embodiment, and those of ordinary skill in the art to which the embodiment pertains will appreciate that various modifications and applications not illustrated above are possible without departing from the essential characteristics of the present embodiment. For example, each component specifically shown in the embodiment can be implemented by modification. In addition, the differences related to these modifications and applications should be interpreted as being included in the scope of the embodiments set forth in the appended claims.

1-10. (canceled)

11. A circuit board comprising:
a core layer;
a first insulating layer disposed on the core layer and having a through hole;
a connection member disposed in the through hole of the first insulating layer; and
a second insulating layer disposed on the first insulating layer while embedding the connection member,
wherein the connection member includes a plurality of insulating members laminated along a vertical direction and including an organic material, and
wherein a height of an upper surface of an insulating member spaced farthest from the core layer among the plurality of insulating members and a height of an upper surface of the first insulating layer are different from each other.

12. The circuit board of claim 11, wherein the upper surface of the insulating member spaced farthest from the core layer is positioned higher than the upper surface of the first insulating layer.

13. The circuit board of claim 12, wherein the insulating member spaced farthest from the core layer includes a first portion that overlaps an inner wall of the through hole along a horizontal direction, and a second portion that is positioned on the first portion and does not overlap the inner wall of the through hole along the horizontal direction.

14. The circuit board of claim 12, wherein the insulating member spaced farthest from the core layer does not overlap with an inner wall of the through hole along a horizontal direction.

15. The circuit board of claim 11, wherein the core layer has a reinforcing member, and
wherein the first insulating layer and the second insulating layer do not have a reinforcing member.

16. The circuit board of claim 11, wherein the connection member includes a plurality of first circuit layers disposed between the plurality of insulating members, and
wherein an upper surface of a first circuit layer spaced farthest from the core layer among the plurality of first circuit layers and the upper surface of the first insulating layer have different heights.

17. The circuit board of claim 16, wherein the first circuit layer spaced farthest from the core layer includes a portion overlapping with an inner wall of the through hole along a horizontal direction.

18. The circuit board of claim 16, wherein the first circuit layer spaced farthest from the core layer does not overlap with an inner wall of the through hole along a horizontal direction.

19. The circuit board of claim 16, further comprising:
a second circuit layer disposed between the first insulating layer and the second insulating layer,
wherein the height of the upper surface of the first circuit layer spaced farthest from the core layer and a height of an upper surface of the second circuit layer are different from each other.

20. The circuit board of claim 19, further comprising:
a via electrode penetrating at least a portion of the second insulating layer along a vertical direction,
wherein the via electrode includes a first via electrode that overlaps the connection member along the vertical direction and is connected to the first circuit layer, and a second via electrode that does not overlap the connection member along the vertical direction and is spaced apart from the first via electrode along the horizontal direction and is connected to the second circuit layer, and
wherein ae thickness of the first via electrode in the vertical direction and a thickness of the second via electrode in the vertical direction are different from each other.

21. The circuit board of claim 20, wherein the height of the upper surface of the first circuit layer spaced farthest from the core layer is greater than the height of the upper surface of the second circuit layer, and
wherein the thickness of the first via electrode in the vertical direction is smaller than the thickness of the second via electrode in the vertical direction.

22. The circuit board of claim 20, wherein the height of the upper surface of the first circuit layer spaced farthest from the core layer is smaller than the height of the upper surface of the second circuit layer, and
wherein the thickness of the first via electrode in the vertical direction is larger than the thickness of the second via electrode in the vertical direction.

23. The circuit board of claim 20, wherein a width of the first via electrode in the horizontal direction is smaller than a width of the second via electrode in the horizontal direction.

24. The circuit board of claim 20, wherein the first via electrode includes a portion overlapping the insulating member spaced farthest from the core layer along the horizontal direction.

25. The circuit board of claim 20, wherein the first via electrode includes a portion overlapping an inner wall of the through hole along the horizontal direction.

26. The circuit board of claim 20, wherein the insulating member spaced farthest from the core layer along the horizontal direction includes a through hole overlapping the first circuit layer along the vertical direction, and
wherein the second insulating layer is provided to fill the through hole of the insulating member.

27. The circuit board of claim 11, further comprising:
a metal layer disposed on the core layer and disposed on a bottom surface of the through hole,
wherein a width of the metal layer in the horizontal direction is different from a width of the through hole in the horizontal direction in a region most adjacent to the metal layer.

28. The circuit board of claim 27, further comprising:
an adhesive member disposed between the metal layer and the connection member,
wherein a width of the metal layer in the horizontal direction, a width of the adhesive member in the horizontal direction, and a width of the connection member in the horizontal direction are different from each other.

29. The circuit board of claim 28, wherein the width of the metal layer in the horizontal direction is larger than the width of the adhesive member in the horizontal direction and the width of the connection member in the horizontal direction, and
wherein the width of the connection member in the horizontal direction is smaller than the width of the metal layer in the horizontal direction and the width of the adhesive member in the horizontal direction.

30. The circuit board of claim 11, further comprising:
an electronic device disposed arranged in a through hole penetrating upper and lower surfaces of the core layer.
